(19) United States
(12) Patent Application Publication
(10) Pub. No.: US 2005/0212034 A1
(43) Pub. Date: Sep. 29, 2005

(54) Nonvolatile semiconductor memory device and manufacturing method thereof

(75) Inventors: Yoshitaka Sasago, Tokyo (JP); Takashi Kobayashi, Tokyo (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/031,484

(22) Filed: Jan. 10, 2005

(30) Foreign Application Priority Data
Mar. 24, 2004 (JP) 2004-087150

(51) Int. Cl. H01L 29/788

(52) U.S. Cl. 257/315

(57) ABSTRACT

A technology realizing decreases of capacitance between the adjoining floating gates and of the threshold voltage shift caused by interference between the adjoining memory cells in a nonvolatile semiconductor memory device with the advances of miniaturization in the period following the 90 nm generation. By having the floating gate 3 of a memory cell with an inverse T-shape and the dimension of a part of the floating gate through the control gate 4 and the second insulator film 8 being smaller than the bottom part of the floating gate, the effects of a threshold voltage shift is reduced maintaining the adequate area of the gap between the floating gate 3 and the control gate 4, decreasing the opposing area of the gap of the floating gates 3 underneath the adjoining word lines WL, maintaining the capacity coupling ratio between the floating gate 3 and the control gate, and reducing the opposing area of the gap of the adjoining floating gates 3.

### CLAIM OF PRIORITY

The present application claims priority from Japanese application JP 2004-087150 filed on Mar. 24, 2004, the content of which is hereby incorporated by reference into this application.

### FIELD OF THE INVENTION

The present invention relates to the field of semiconductor devices and manufacturing methods thereof, and more particularly to an improved method for nonvolatile semiconductor memory devices which can be programmed electrically.

### BACKGROUND OF THE INVENTION

A so-called flash memory is known as one for which bulk erasing is possible in nonvolatile semiconductor memory devices, in which electric programming is possible. Because flash memory is handy to carry, has excellent shock resistance, and electric bulk erasing is possible, it has seen a rapidly increasing demand in these days as a memory device for personal digital assistants such as mobile personal computers and digital still cameras. In order to expand the market, a reduction in bit cost by a decrease in the memory cell size is a demand factor. A reduction in the physical cell size by a reduction in the process rule or a reduction in the cell size per bit by multilevel technologies has been carried out to solve this problem.

Moreover, in order to make the programming/erasing speed fast enough, it is necessary in a flash memory to make the so-called coupling ratio large enough, and to make large the ratio of the floating gate voltage to the voltage biasing the control gate. The coupling ratio is expressed as Cfg-cg/Ctot which is a ratio of the capacitance Cfg-cg between the floating gate and the control gate and the total capacitance around the floating gate, Ctot.

In order to carry out programming/erasing by a control gate voltage lower than 18 V, it is necessary to control the coupling ratio to be about 0.6 or more. In the prior art, a shape sticking out to the side of the control gate has been used to make the coupling ratio appropriate (Non-patent documents 1 and 2). Actually, in a flash memory of the prior art up to the 130 nm generation, sufficient programming/erasing speed can be achieved by using these shapes of the floating gate.

Technologies to improve the coupling ratio are also disclosed in the patent documents, JP-A No.335588/1993 (Patent document 1), JP-A No.8155/1997 (Patent document 2), and JP-A No.17038/1999 (Patent document 3).
[Patent document 1] JP-A No.335588/1993
[Patent document 2] JP-A No.8155/1997
[Patent document 3] JP-A No.17038/1999
[Non-patent document 1] International Electron Devices Meeting, 2002 pp. 919-922
[Non-patent document 2] 2003 Symposium on VLSI Technology Digest Symposium pp. 89-90

However, in the aforementioned patent documents 1, 2, and 3, it is impossible to reduce the memory cell size because the finest part of the floating gate is the minimum feature size. That is, it is impossible for it to be used in a current and future flash memory in which the floating gate and word line have to be fabricated in the minimum feature size.

Additionally, a new problem arises in the aforementioned non-patent documents 1 and 2 when the reduction in memory cell size progresses further. That is, there is the problem that the capacitive coupling between the floating gates becomes larger, and the interference between the adjoining floating gates becomes larger because the gap between the adjoining floating gates becomes smaller. Concretely, a threshold voltage shift in the memory cell of interest in proportion to the threshold voltage shift (change in voltage) of the adjoining memory cell becomes so large that it cannot be ignored. Especially, in the case when a multilevel storage technique is used, it causes the performance and reliability to be decreased because it is necessary to make the threshold voltage gap of each level larger taking into consideration the threshold voltage shift. A monolith-type floating gate used in the prior art has a large opposing area at the gap of the adjoining floating gates. Therefore, from the 90 nm generation on, a reduction in the bit cost using a multilevel storage technique and maintaining the programming/erasing speed have not been compatible.

### SUMMARY OF THE INVENTION

It is the general objective of the present invention to provide a technique for reducing the capacitance between adjoining floating gates, and for lowering the threshold voltage shift by interference between adjoining memory cells in a nonvolatile semiconductor memory device in which a reduction in the memory cell size has progressed since 90 nm generation.

The aforementioned and other objectives and new features of this invention will be more clearly understood from the following descriptions and accompanying drawings of these detailed descriptions.

The following is a brief description of a typical embodiment disclosed in the present invention.

A nonvolatile semiconductor memory device of the present invention comprises a first conductive well formed on a semiconductor substrate, a plurality of floating gates lined up at a uniform spacing on the semiconductor substrate along a second direction parallel to the semiconductor substrate and perpendicular to the first direction through a gate insulator film, and a control gate (word line) lying along the first direction formed through a second insulator film covering the floating gate, in which the dimension along the first direction at the part of the floating gate connected to the second insulator film is made smaller than the dimension along the first direction at the part of the floating gate connected to the gate insulator film.

A manufacturing method of a nonvolatile semiconductor memory device of the present invention comprises a process for forming a first conductive well on a semiconductor substrate, a process for forming a gate insulator film on the semiconductor film, a process for forming a plurality of floating gates lined up at a uniform spacing along a second direction parallel to the semiconductor substrate and perpendicular to the first direction on the well through the gate insulator film, and a process for forming a plurality of third gates connected to the semiconductor substrate through the third insulator film and to the floating gate through the fourth insulator layer lying along the second direction, and a process for forming a plurality of control gates (word lines) connected to the floating gate through the second insulator film and to the third gate through the fifth and second insulator film lying along the first direction, in which the dimension along the first direction at the part of the floating gate connected to the second insulator film is made smaller than the dimension along the first direction at the part of the floating gate connected to the gate insulator film.

The following is a brief description of a typical embodiment disclosed in the present invention.

In a nonvolatile semiconductor memory device, the threshold voltage shift of the memory cell caused by capacitive coupling between the adjoining floating gates becomes remarkable with decreasing the pitch of the control gate (word line). The threshold voltage shift of the memory cell can be reduced by decreasing the opposing area between the adjoining floating gates. Because of this, the threshold value level gap of each state of the memory cell can be made narrower, so that the programming/erasing performance can be improved. Moreover, it has the effect of preventing a read error by the above-mentioned threshold voltage shift of the memory cell, resulting in the reliability of the nonvolatile semiconductor memory device being improved.

### BRIEF DESCRIPTION OF THE DRAWINGS

FIG. 1 is a main plane diagram schematically illustrating one example of a nonvolatile semiconductor memory device described in the first embodiment of the present invention;

FIGS. 2A, 2B, and 2C are main cross-sectional views at the positions of line A-A′, line B-B′, and line C-C′, respectively, in FIG. 1;

FIG. 3 is a schematic drawing of a circuit diagram of a memory array illustrating a voltage condition while reading, described in the first embodiment of the present invention;

FIG. 4 is a schematic drawing of a circuit diagram of a memory array illustrating a voltage condition while programming, described in the first embodiment of the present invention;

FIGS. 5A, 5B, and 5C are main cross-sectional views illustrating one example of a manufacturing method of a nonvolatile semiconductor memory device described in the first embodiment of the present invention;

FIGS. 6A, 6B, and 6C are main cross-sectional views illustrating the same position shown in FIG. 5 during a manufacturing process of the nonvolatile semiconductor memory device in connection with FIG. 5;

FIGS. 7A, 7B, and 7C are main cross-sectional views illustrating the same position shown in FIG. 5 during a manufacturing process of the nonvolatile semiconductor memory device in connection with FIG. 6;

FIGS. 8A and 8B are main cross-sectional views illustrating the same positions shown in FIG. 5 during a manufacturing process of the nonvolatile semiconductor memory device in connection with FIG. 7;

FIG. 9 is a main plane view illustrating the nonvolatile semiconductor memory device during a manufacturing process in connection with FIG. 8;

FIGS. 10A, 10B, and 10C are main cross-sectional views at the positions of line A-A′, line B-B′, and line C-C′, respectively, in FIG. 9;

FIG. 11 is a graphical diagram showing the threshold voltage shift of an inverse T-shaped floating gate and the threshold voltage shift of a monolith-type floating gate described in the first embodiment of the present invention;

FIGS. 12A and 12B are main cross-sectional views illustrating the same positions shown in FIG. 5 during a manufacturing process of the nonvolatile semiconductor memory device in connection with FIG. 7B;

FIGS. 13A, 13B, and 13C are main cross-sectional views illustrating one example of a manufacturing method of the nonvolatile semiconductor memory device described in the second embodiment of the present invention;

FIGS. 14A, 14B, and 14C are main cross-sectional views illustrating the same positions shown in FIG. 13 during a manufacturing process of the nonvolatile semiconductor memory device in connection with FIG. 13;

FIG. 15 is a main plane view illustrating a nonvolatile semiconductor memory device during a manufacturing process in connection with FIG. 14;

FIGS. 16A, 16B, and 16C are main cross-sectional views illustrating the same positions shown in FIG. 13 during a manufacturing process of the nonvolatile semiconductor memory device in connection with FIG. 14;

FIGS. 17A, 17B, and 17C are main cross-sectional views illustrating one example of a manufacturing method of the nonvolatile semiconductor memory device described in the third embodiment of the present invention;

FIGS. 18A, 18B, and 18C are main cross-sectional views illustrating the same positions shown in FIG. 17 during a manufacturing process of the nonvolatile semiconductor memory device in connection with FIG. 17; and

FIGS. 19A, 19B, and 19C are main cross-sectional views illustrating the same positions shown in FIG. 17 during a manufacturing process of the nonvolatile semiconductor memory device in connection with FIG. 18.

FIG. 20 is main cross-sectional views illustrating the same positions shown in FIG. 17 during a manufacturing process of the nonvolatile semiconductor memory device in connection with FIG. 19;

FIGS. 21A and 21B are main cross-sectional views illustrating the same positions shown in FIG. 17 during a manufacturing process of the nonvolatile semiconductor memory device in connection with FIG. 20;

FIGS. 22A and 22B are main cross-sectional views illustrating the same positions shown in FIG. 17 during a manufacturing process of the nonvolatile semiconductor memory device in connection with FIG. 21;

FIGS. 23A, 23B, and 23C are main cross-sectional views illustrating one example of a manufacturing method of the nonvolatile semiconductor memory device described in the fourth embodiment of the present invention;

FIGS. 24A, 24B, and 24C are main cross-sectional views illustrating the same positions shown in FIG. 23 during a manufacturing process of the nonvolatile semiconductor memory device in connection with FIG. 23;

FIGS. 25A, 25B, and 25C are main cross-sectional views illustrating the same positions shown in FIG. 23 during a manufacturing process of the nonvolatile semiconductor memory device in connection with FIG. 24;

FIG. 26 is a main plane view illustrating a nonvolatile semiconductor memory device during a manufacturing process in connection with FIG. 25;

FIGS. 27A and 27B are main cross-sectional views at the positions of line A-A′ and line B-B′ of FIG. 26, respectively;

FIGS. 28A and 28B are main cross-sectional views at the positions of line C-C′ and line D-D′ of FIG. 26, respectively.

FIGS. 29A and 29B are main cross-sectional views illustrating the same positions shown in FIG. 27 during a manufacturing process of the nonvolatile semiconductor memory device in connection with FIGS. 26, 27, and 28;

FIGS. 30A and 30B are main cross-sectional views illustrating the same positions shown in FIG. 28 during a manufacturing process of the nonvolatile semiconductor memory device in connection with FIGS. 26, 27, and 28;

FIGS. 31A and 31B are main cross-sectional views illustrating the same positions shown in FIG. 27 during a manufacturing process of the nonvolatile semiconductor memory device in connection with FIGS. 29 and 30;

FIGS. 32A and 32B are main cross-sectional views illustrating the same positions shown in FIG. 28 during a manufacturing process of the nonvolatile semiconductor memory device in connection with FIGS. 29 and 30;

FIGS. 33A and 33B are main cross-sectional views illustrating the same positions shown in FIG. 27 during a manufacturing process of the nonvolatile semiconductor memory device in connection with FIGS. 31 and 32;

FIGS. 34A and 34B are main cross-sectional views illustrating the same positions shown in FIG. 28 during a manufacturing process of the nonvolatile semiconductor memory device in connection with FIGS. 31 and 32;

FIGS. 35A and 35B are main cross-sectional views illustrating the same positions shown in FIG. 27 during a manufacturing process of the nonvolatile semiconductor memory device in connection with FIGS. 33 and 34;

FIGS. 36A and 36B are main cross-sectional views illustrating the same positions shown in FIG. 28 during a manufacturing process of the nonvolatile semiconductor memory device in connection with FIGS. 33 and 34;

FIGS. 37A and 37C are main cross-sectional views illustrating the same positions shown in FIG. 27 during a manufacturing-process of the nonvolatile semiconductor memory device in connection with FIGS. 35 and 36;

FIGS. 38A and 38B are main cross-sectional views illustrating the same positions shown in FIG. 28 during a manufacturing process of the nonvolatile semiconductor memory device in connection with FIGS. 35 and 36;

FIGS. 39A and 39B are schematic drawings of circuit diagrams of a memory array in the fifth embodiment of the present invention. 39A shows one example of the voltage condition while reading, and 39B shows one example of the voltage condition while programming;

FIGS. 40A, 40B, and 40C are main cross-sectional views illustrating one example of a manufacturing method of the nonvolatile semiconductor memory device described in the fifth embodiment of the present invention;

FIGS. 41A, 41B, and 41C are main cross-sectional views illustrating the same positions shown in FIG. 40 during a manufacturing process of the nonvolatile semiconductor memory device in connection with FIG. 40;

FIGS. 42A, 42B, and 42C are main cross-sectional views illustrating the same positions shown in FIG. 40 during a manufacturing process of the nonvolatile semiconductor memory device in connection with FIG. 41;

FIG. 43 is a main plane view illustrating a nonvolatile semiconductor memory device during a manufacturing process in connection with FIG. 42;

FIGS. 44A and 44B are main cross-sectional views at the positions of line A-A′ and line B-B′ of FIG. 43, respectively;

FIGS. 45A and 45B are main cross-sectional views at the positions of line C-C′ and line D-D′ of FIG. 43, respectively;

FIGS. 46A, 46B, and 46C are main cross-sectional views illustrating one example of a manufacturing method of the nonvolatile semiconductor memory device described in the sixth embodiment of the present invention;

FIGS. 47A, 47B, and 47C are main cross-sectional views illustrating the same positions shown in FIG. 46 during a manufacturing process of the nonvolatile semiconductor memory device in connection with FIG. 46;

FIGS. 48A, 48B, and 48C are main cross-sectional views illustrating the same positions shown in FIG. 46 during a manufacturing process of the nonvolatile semiconductor memory device in connection with FIG. 47;

FIGS. 49A, 49B, and 49C are main cross-sectional views illustrating the same positions shown in FIG. 46 during a manufacturing process of the nonvolatile semiconductor memory device in connection with FIG. 48;

FIGS. 50A, 50B, and 50C are main cross-sectional views illustrating one example of a manufacturing method of the nonvolatile semiconductor memory device described in the seventh embodiment of the present invention;

FIGS. 51A, 51B, and 51C are main cross-sectional views illustrating the same positions shown in FIG. 50 during a manufacturing process of the nonvolatile semiconductor memory device in connection with FIG. 50;

FIGS. 52A and 52B are main cross-sectional views illustrating the same positions shown in FIG. 50 during a manufacturing process of the nonvolatile semiconductor memory device in connection with FIG. 51;

FIG. 53 is a main plane view illustrating a nonvolatile semiconductor memory device during a manufacturing process in connection with FIG. 52;

FIGS. 54A and 54B are main cross-sectional views at the positions of line A-A′ and line B-B′ of FIG. 53, respectively;

FIGS. 55A and 55B are main cross-sectional views at the positions of line C-C′ and line D-D′ of FIG. 53, respectively;

FIGS. 56A and 56B are main cross-sectional views illustrating the same positions shown in FIG. 54 during a manufacturing process of the nonvolatile semiconductor memory device in connection with FIGS. 53, 54, and 55;

FIGS. 57A and 57B are main cross-sectional views illustrating the same positions shown in FIG. 55 during a manufacturing process of the nonvolatile semiconductor memory device in connection with FIGS. 53, 54, and 55;

FIGS. 58A and 58B are main cross-sectional views illustrating the same positions shown in FIG. 54 during a manufacturing process of the nonvolatile semiconductor memory device in connection with FIGS. 56 and 57;

FIGS. 59A and 59B are main cross-sectional views illustrating the same positions shown in FIG. 55 during a manufacturing process of the nonvolatile semiconductor memory device in connection with FIGS. 56 and 57;

FIGS. 60A and 60B are main cross-sectional views illustrating the same positions shown in FIG. 54 during a manufacturing process of the nonvolatile semiconductor memory device in connection with FIGS. 58 and 59;

FIGS. 61A and 61B are main cross-sectional views illustrating the same positions shown in FIG. 55 during a manufacturing process of the nonvolatile semiconductor memory device in connection with FIGS. 58 and 59;

FIGS. 62A and 62B are main cross-sectional views illustrating the same positions shown in FIG. 54 during a manufacturing process of the nonvolatile semiconductor memory device in connection with FIGS. 60 and 61; and

FIGS. 63A and 63B are main cross-sectional views illustrating the same positions shown in FIG. 55 during a manufacturing process of the nonvolatile semiconductor memory device in connection with FIGS. 60 and 61.

### DETAILED DESCRIPTION OF THE PREFERRED EMBODIMENTS

The following is a detailed description of the embodiments of the present invention with reference to the accompanying drawings. In all the drawings to describe the embodiments, like reference characters designate corresponding parts in several drawings and the repetition of the description is omitted.

### First Embodiment

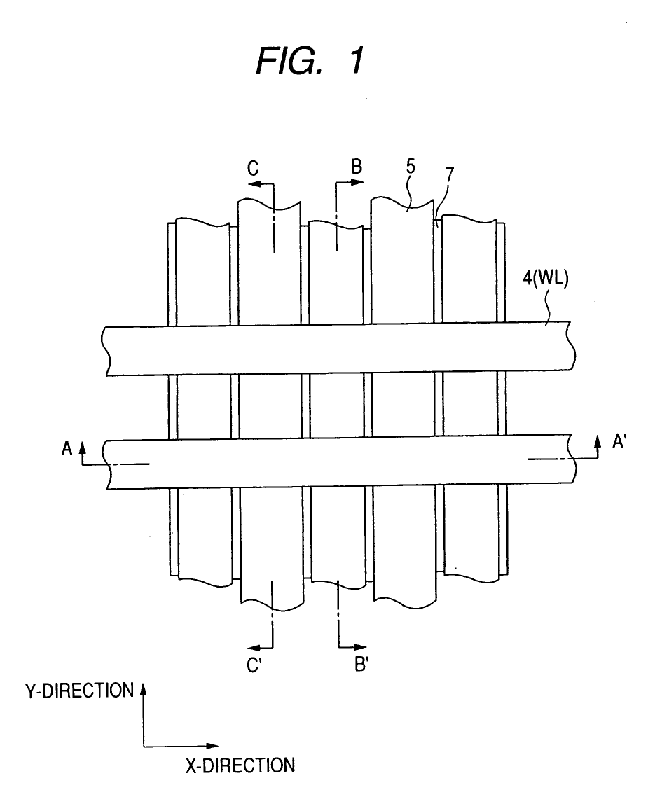

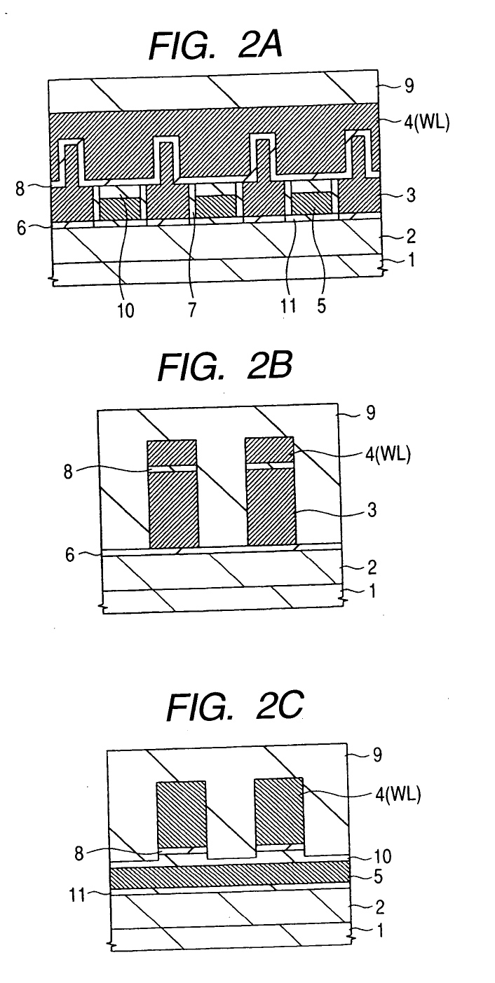

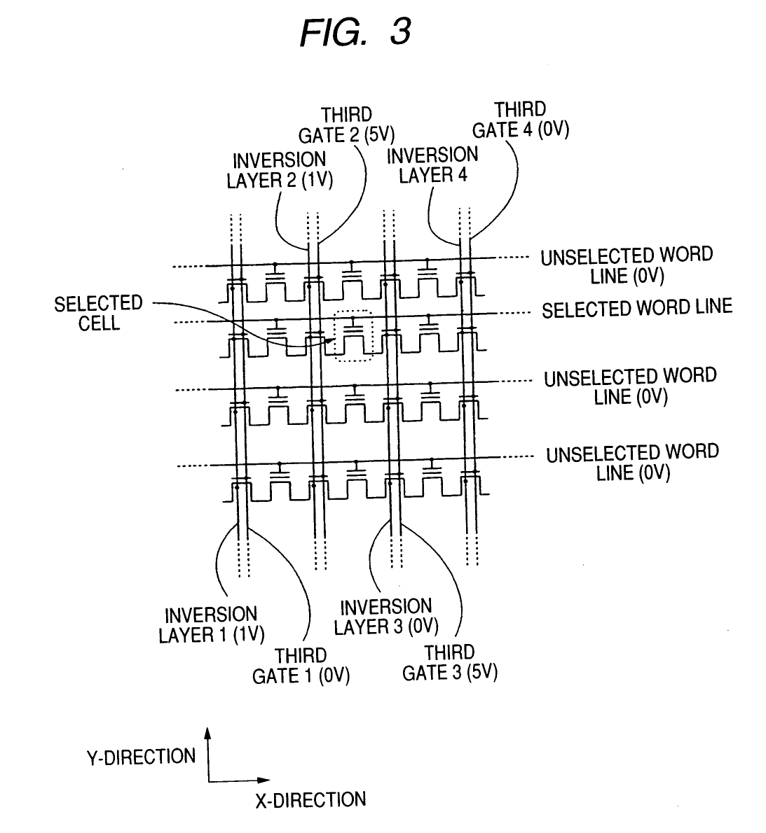

FIG. 1 is a main plane diagram schematically illustrating one example of a nonvolatile semiconductor memory device described in the first embodiment of the present invention. FIGS. 2A, 2B, and 2C are main cross-sectional views at the positions of line A-A′, line B-B′, and line C-C′ of FIG. 1, respectively. FIG. 3 is a schematic circuit diagram of a memory array illustrating the first embodiment of a nonvolatile semiconductor memory device of the present invention. A part of the material section is omitted to make the diagram easy to see.

The nonvolatile semiconductor memory device described in the first embodiment of the present invention comprises a so-called memory cell of a flash memory, wherein this memory cell comprises a well 2 formed on the main surface of the semiconductor substrate 1, the floating gate (first gate) 3, the control gate (second gate) 2, and the third gate 5.

The control gate 4 of each memory cell is connected along the line direction (X direction: first direction) to form the word line WL. The floating gate 3 and well 2 are separated by the gate insulator film (first insulator film) 6; the floating gate 3 and the third gate 5 are separated by the fourth insulator film 7; and the floating gate 3 and the control gate 4 are separated by the second insulator film 8. Both floating gates 3 are separated by the sixth insulator film 9 along the direction perpendicular to the control gate 4. Moreover, the third gate 5 and the control gate 4 are separated by the second insulator film 8 and the fifth insulator film 10, and the third gate 5 and well 2 are separated by the gate insulator film (third insulator film) 11.

The source and drain of the memory cell consist of an inversion layer, which is formed underneath the third gate 5 by biasing a voltage to the third gate 5 lying along the direction (Y direction: second direction) perpendicular to the direction where the control gate 4 lies (X direction), and they function as a local data line. That is, the nonvolatile semiconductor memory device described in the first embodiment of the present invention consists of a so-called contactless array which has no contact hole in each memory cell. Moreover, since the inversion layer is used as a local data line, a diffusion layer is not necessary in the memory array, and it makes it possible to reduce the data line pitch.

As shown in FIG. 3, an inversion layer is formed underneath the third gate by biasing a voltage of about 5 V to the third gate located on both sides of the selected cell and used as a drain and source while reading. Making the unselected cell OFF state by biasing a voltage of 0 V or a negative voltage of −2 V in some cases to the unselected word line, and then the threshold voltage of the memory cell is evaluated by biasing a voltage to the word line of the selected bit.

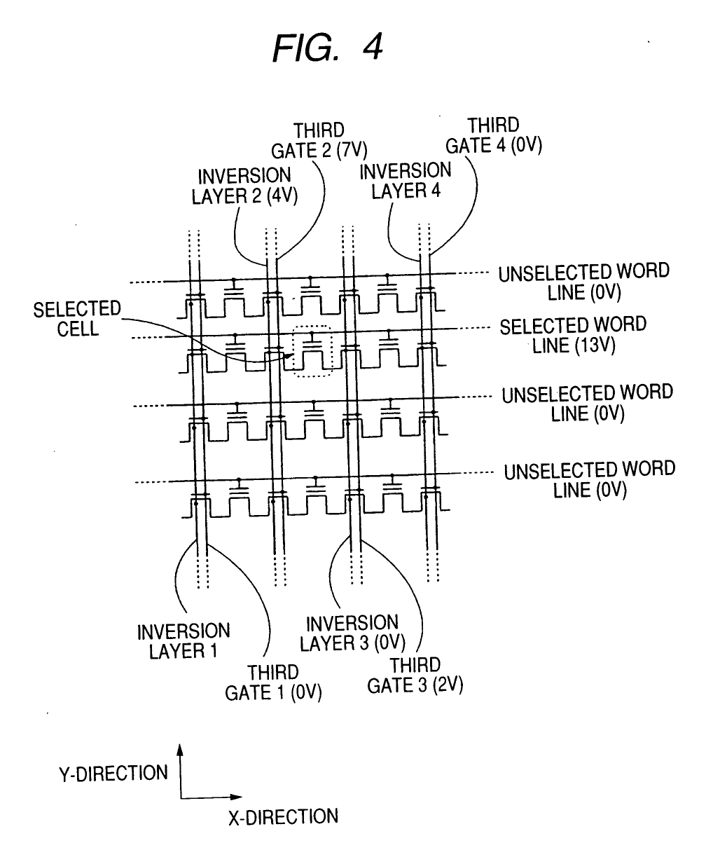

Moreover, as shown in FIG. 4, the source and well are kept to 0 V while programming by biasing about 13 V to the control gate (selected word line), about 4 V to the drain, about 7 V to the third gate of the drain side, and about 2 V to the third gate on the source side in the selected cell. Because of this, a channel is formed in the well underneath the third gate, and hot electrons are generated in the channel at the end of the floating gate of the source side, resulting in electrons being injected in the floating gate.

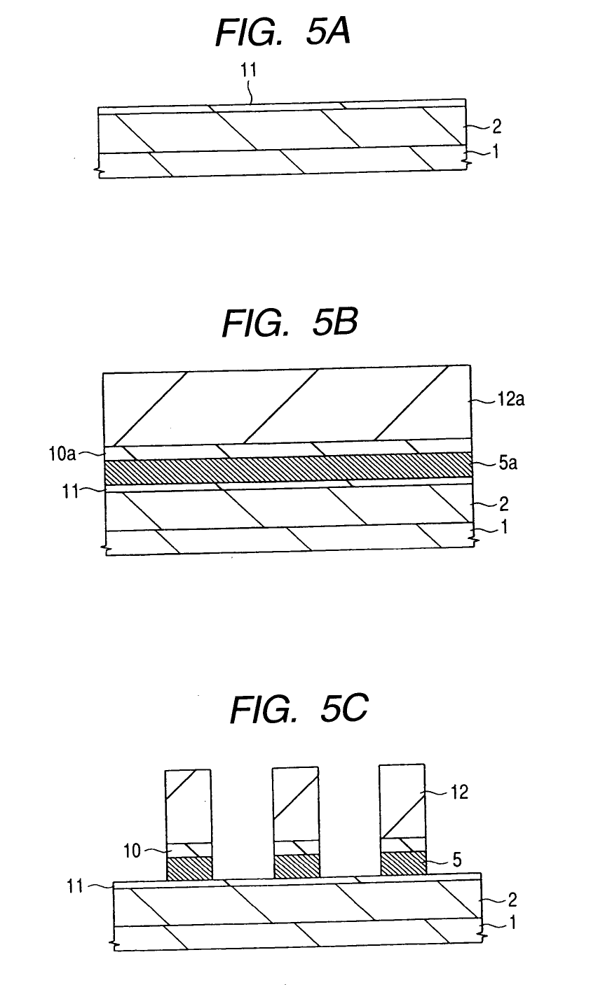

FIGS. 5 to 10 are main cross-sectional diagrams or main plane diagrams schematically illustrating one example of the manufacturing method of a nonvolatile semiconductor memory device described in the first embodiment of the present invention.

First, the p-type (first conductive) well 2 is formed on a semiconductor substrate, and a gate insulator film 11 about 10 nm thick is formed by, for instance, a thermal oxidation method (FIG. 5A).

Next, a phosphorus (P) doped polysilicon film 5a which will become the third gate, a silicon nitride film 10a which will become the fifth insulator film, and the dummy silicon oxide film 12a are deposited in order (FIG. 5b). For instance, a Chemical Vapor Deposition (CVD) method can be used for deposition of the polysilicon film 5a, the silicon nitride film 10a, and the dummy silicon oxide film 12a.

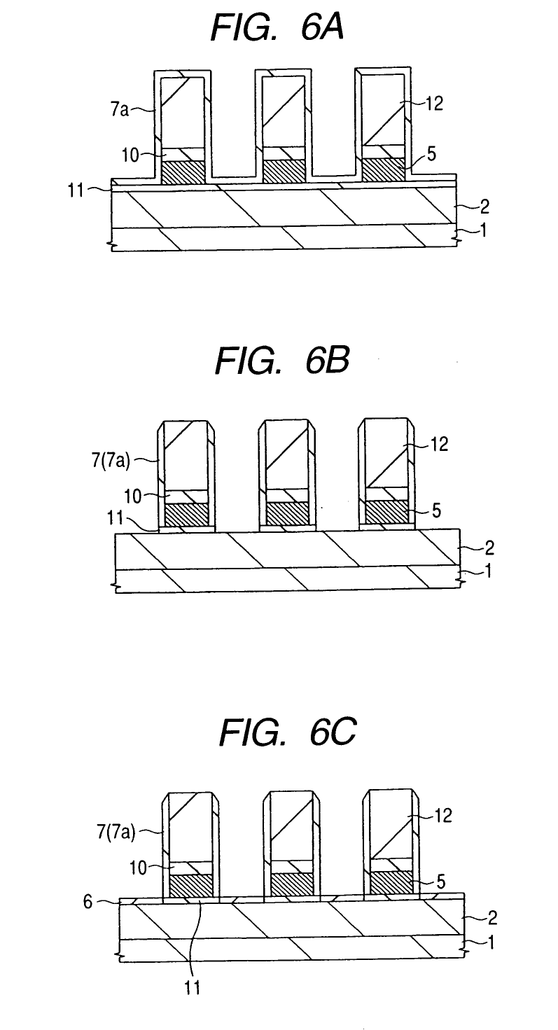

Next, the dummy silicon oxide film 12a, the silicon nitride film 10a, and polysilicon film 5a are patterned by lithography or a dry etching technique. The dummy silicon oxide film pattern 12, the fifth insulator film 10, and the third gate 5 are formed by etching of the dummy silicon oxide film 12a, the silicon nitride film 10a, and the polysilicon film 5a, respectively (FIG. 5C). The dummy silicon oxide film pattern 12, the fifth insulator film 10, and the third gate 5 are patterned in a stripe shape so as to be formed lying along the Y direction (the second direction). Afterwards, the silicon oxide layer 7a is deposited to avoid the space parts of the aforementioned stripe-shaped pattern from being filled completely (FIG. 6A).

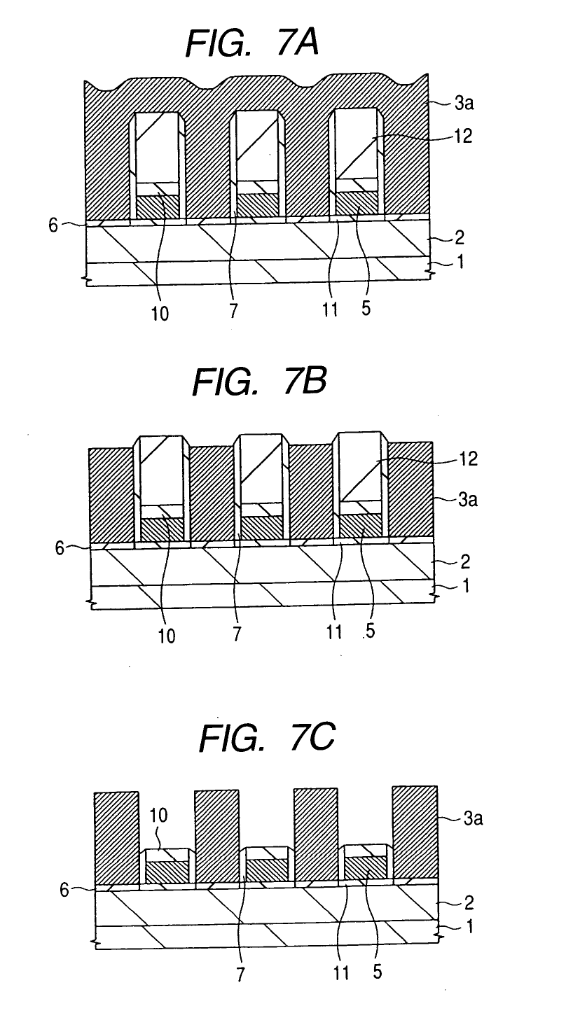

Next, the fourth dielectric layer 7 is formed along the side walls of the dummy silicon oxide film pattern 12, the fifth insulator film 10, and the third gate 5 by selectively etching back the silicon oxide layer 7a (FIG. 6B). At this time, the gate insulator film 11 is also removed at the space parts of the stripe-shaped pattern formed lying along the aforementioned Y direction. Next, the gate insulator film 6 is formed by a thermal oxidation or CVD method (FIG. 6C). Then, the polysilicon film 3a which will become the floating gate is deposited to completely fill the aforementioned space (FIG. 7A).

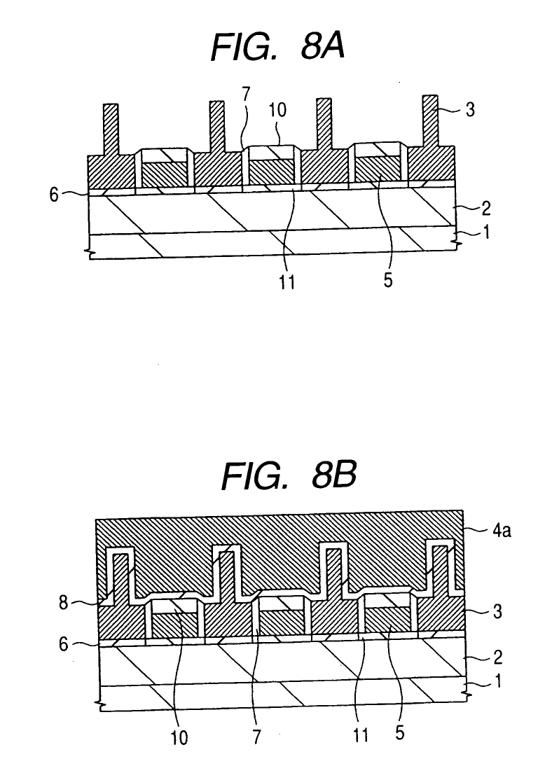

Next, the polysilicon film 3a is removed by the etch back technique or Chemical Mechanical Polishing (CMP) until the dummy silicon oxide pattern 12 becomes exposed (FIG. 7B). Moreover, the dummy silicon oxide film pattern 12 and the fourth insulator film 7 are removed by a dry etching or a wet etching technique until the fifth insulator film 10 becomes exposed (FIG. 7C). Herein, the polysilicon film 3a is etched by a dry etching or a wet etching technique using an isotropic etching condition (FIG. 8A). According to this process, the polysilicon film 3a is formed to be a stripe-shaped pattern with an inverse T-shape cross-section, consisting of the floating gate. In this step, the stripe-shaped pattern is lying along the Y direction.

In the next step, the second insulator film 8 is formed, which electrically insulates the floating gate 3 from the control gate. For instance, a silicon oxide layer or stacked layer consisting of a silicon oxide film/silicon nitride film/silicon oxide film can be used for this second insulator film 8. Next, the control gate material 4a is deposited. For instance, a stacked film consisting of a polysilicon film/tungsten nitride film/tungsten film, which is a so-called polymetal film, can be used for this control gate material 4a (FIG. 8B).

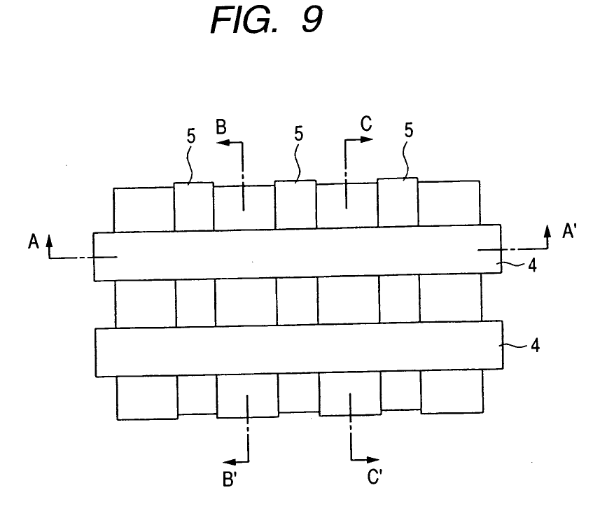

The control gate 4 (word line WL) is formed by patterning using a lithography or a dry etching technique (FIG. 9). The control gate 4, the second insulator film 8, and the floating gate 3 are processed in one step by using a stripe-shaped mask pattern lying along the X direction while patterning.

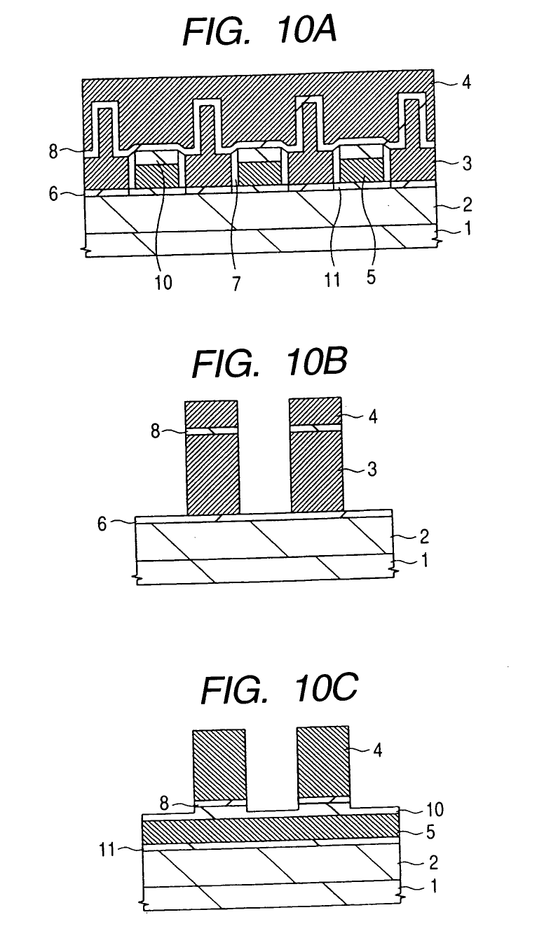

The line cross-section A-A′, line cross-section B-B′, and line cross-section C-C′ of FIG. 9 become FIGS. 10A, 10B, and 10C, respectively, after patterning the word line.

Subsequently, the contact hole reaching the control gate 4, the well 2, and the third gate 5 and the contact hole for feeding power to the inversion layer to become a source and drain located outside of the memory array are formed after forming the interlayer dielectric film. Then, a metallic film is deposited and patterned to be an interconnection, resulting in a memory cell being completed.

In the memory cell of a nonvolatile semiconductor memory fabricated using the above-mentioned process, a part of the floating gate 3 through the control gate 4 and the second insulator film 8 has a smaller dimension than the bottom part of the floating gate 3. Because of this, the opposing areas between the floating gates 3 underneath the adjoining word line WL can be reduced while keeping an adequate area between the floating gate 3 and the control gate 4. That is, maintaining the coupling ratio between the control gate 4 and the floating gate 3 can be compatible with reducing the capacitive coupling between the floating gates 3 underneath the adjoining word line WL. As a result, maintaining the programming/erasing properties can be compatible with reducing the threshold voltage shift caused by changing the adjoining cell conditions.

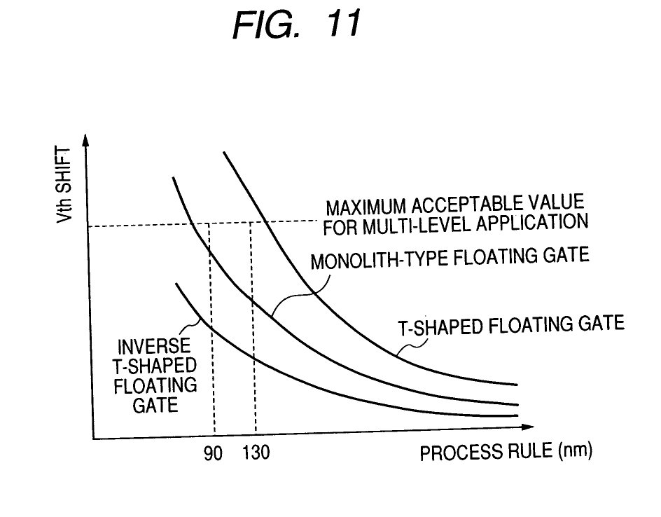

FIG. 11 shows the threshold voltage shift of an inverse T-shaped floating gate described in the first embodiment of the present invention and a monolith-type floating gate. There is a clear indication that the effects are obvious, particularly in the case when the word line pitch is small.

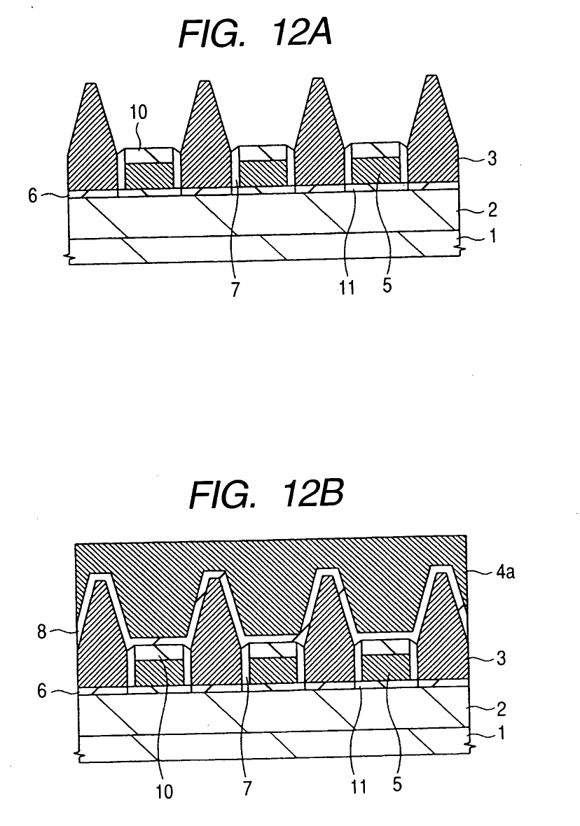

In FIG. 7C, it is possible that the polysilicon film 3a is etched isotropically at the same time when the dummy silicon oxide pattern 12 and the fourth insulator layer 7 are removed. According to this technique, the upper part of the floating gate can be tapered as shown in FIG. 12A. The memory cell shown in FIG. 12B can be fabricated by using the same process and, even in this shape, it is possible that the opposing areas between the floating gates 3 underneath the adjoining word line WL can be reduced while maintaining an adequate area between the floating gate 3 and the control gate 4. That is, maintaining the programming/erasing properties can be compatible with reducing the threshold voltage shift caused by changing the adjoining cell conditions.

### Second Embodiment

In the aforementioned first embodiment, the shape of the floating gate was made in an inverse T-shape by isotropically etching a part of the stripe-shaped polysilicon film, but it can be made in an inverse T-shape by forming the floating gate in two polysilicon layers.

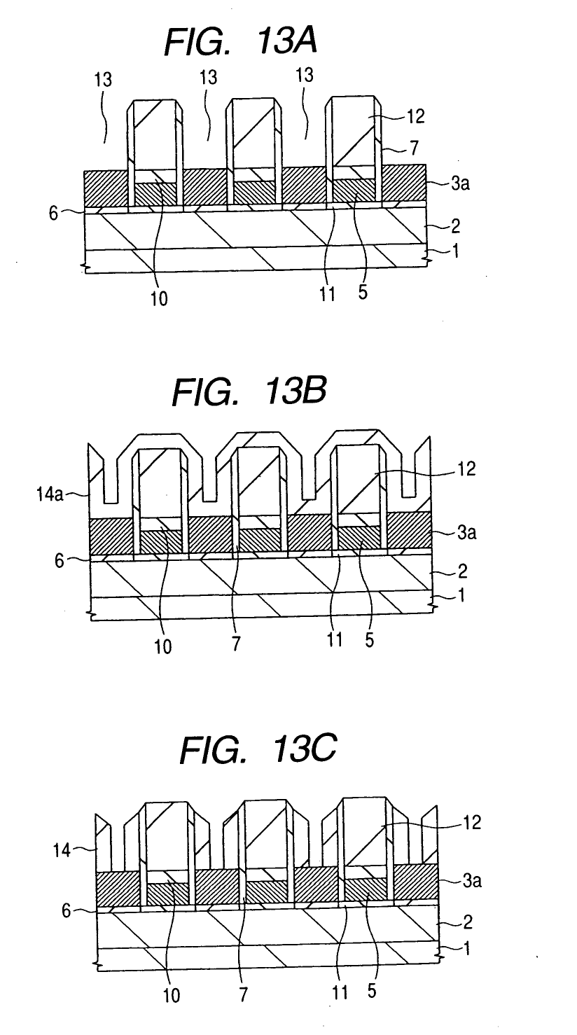

FIGS. 13 to 16 are main cross-sections and main plane diagrams schematically illustrating one example of a nonvolatile semiconductor memory device described in the second embodiment of the present invention.

First, the same as the processes described in FIGS. 5A to 7A of the aforementioned first embodiment, the fourth insulator film 7 is formed along the side walls of the dummy silicon oxide film pattern 12 patterned in a stripe shape, the fifth insulator film 10, and the third gate 5. And then, the polysilicon film 3a which will become the first layer of the floating gate is deposited to completely fill the space of the stripe-shaped pattern. Next, the polysilicon film 3a is partially removed by etch back to form the space 13 (FIG. 13A) Moreover, the silicon oxide film 14a is deposited to avoid the space 13 from being filled completely (FIG. 13B). Furthermore, the side wall 14 consisting of the silicon oxide film 14a is formed by etch back of the silicon oxide layer 14a (FIG. 13C)

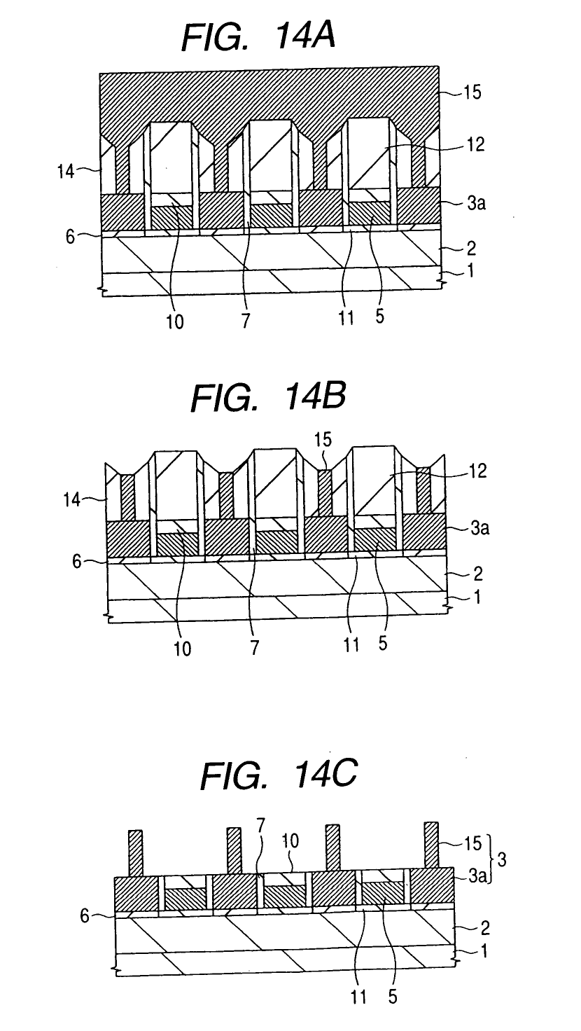

Next, the polysilicon film 15 is deposited to be the second layer of the floating gate (FIG. 14A). The polysilicon film 3a is electrically connected to the polysilicon layer 15.

Next, the polysilicon film 15 is partially removed by etch back or CMP, and the upper parts of the dummy silicon oxide film pattern 12, the fourth insulator film 7, and the side wall 14 are exposed (FIG. 14B). Then, the dummy silicon oxide film pattern 12, a part of the fourth insulator film 7, and the side wall 14 are removed by a wet etching or a dry etching technique and the fifth insulator film are exposed (FIG. 14C).

According to this process, the polysilicon pattern consisting of a stacked layer of the polysilicon layer 3a and the polysilicon film 15 is formed to be a stripe-shaped pattern with an inverse T-shaped cross-section, consisting of the floating gate 3. In this step, the polysilicon pattern consisting of a stacked layer of the polysilicon film 3a and the polysilicon film 15 is lying along the Y direction.

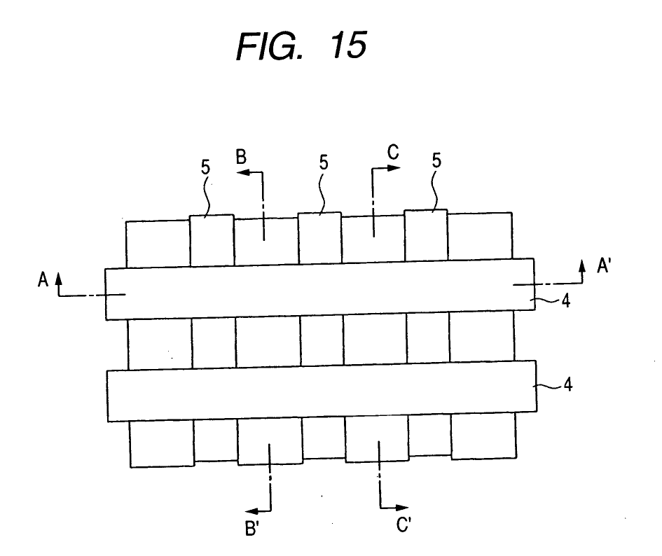

In the next step, the same as the aforementioned first embodiment, the second insulator layer 8, electrically insulating the floating gate 3 from the control gate, is formed; the control gate material is deposited; and the control gate 4 (word line WL) is formed by patterning using lithography and a dry etching technique (FIG. 15). The control gate 4, the second insulator film 8, and the floating gate 3 are processed in one step by using a stripe-shaped mask pattern lying along the X direction while patterning.

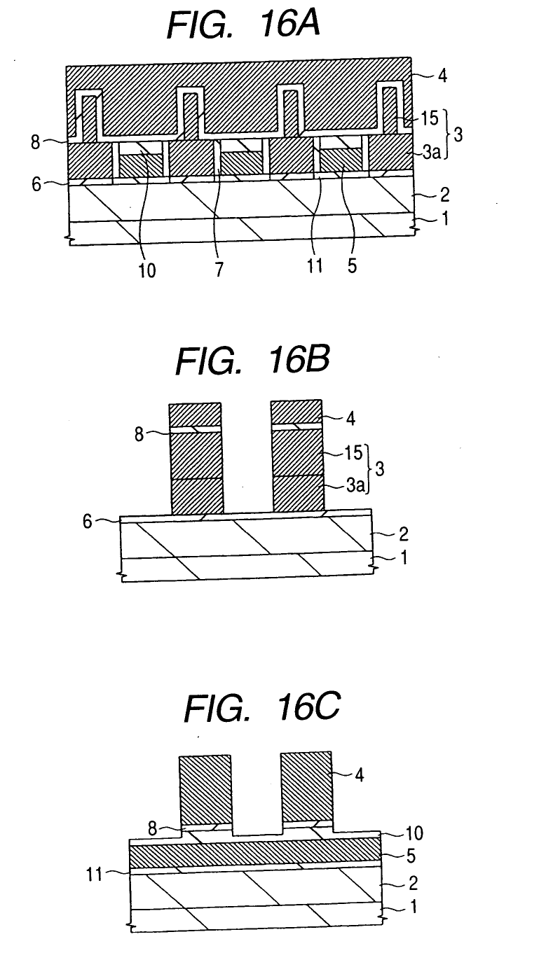

The line cross-section A-A′, the line cross-section B-B′, and the line cross-section C-C′ of FIG. 15 become FIGS. 16A, 16B, and 16C, respectively, after patterning the word line.

Subsequently, the contact hole reaching the control gate 4, the well 2, and the third gate 5, and the contact hole for feeding power to the inversion layer to become a source and drain located outside of the memory array are formed after forming the interlayer dielectric film. Then, a metallic film is deposited and patterned to be an interconnection, resulting in a memory cell being completed.

In the memory cell of a nonvolatile semiconductor memory fabricated using the above-mentioned process, the part of the floating gate 3 through the control gate 4 and the second insulator film 8 has a smaller dimension than the bottom part of the floating gate 3. Because of this, the opposing area between the floating gates 3 underneath the adjoining word line WL can be reduced while maintaining an adequate area between the floating gate 3 and the control gate 4. That is, maintaining the coupling ratio between the control gate 4 and the floating gate 3 can be compatible with reducing the capacitive coupling between the floating gates 3 underneath the adjoining word line WL. As a result, maintaining the programming/erasing properties can be compatible with reducing the threshold voltage shift caused by changing the adjoining cell conditions.

### Third Embodiment

In the aforementioned second embodiment, the space for forming the polysilicon pattern of the second layer of the floating gate was fabricated by etching back the first layer of the floating gate. On the other hand, in the third embodiment, another example to fabricate a space will be described in which the polysilicon pattern of the second layer is formed

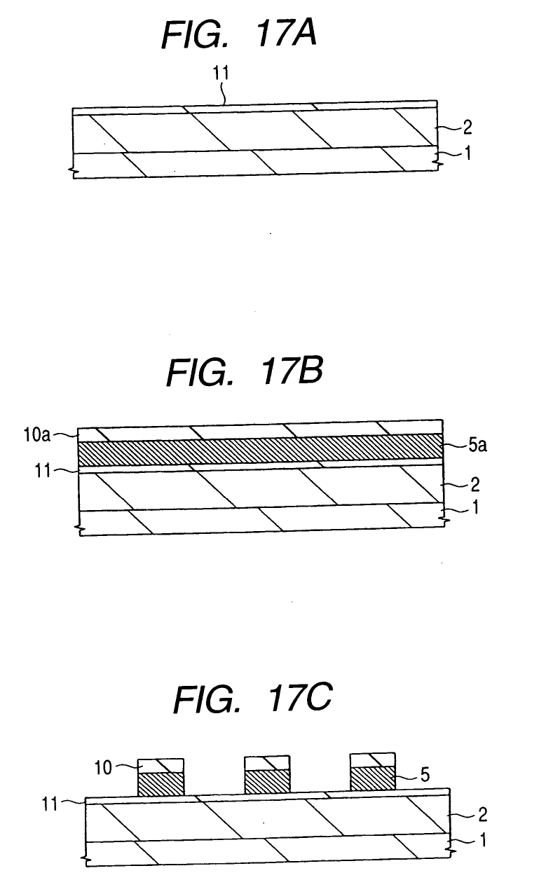

FIGS. 17 to 22 are main plane diagrams schematically illustrating one example of a nonvolatile semiconductor memory device described in the third embodiment of the present invention.

First, a p-well 2 is formed on the semiconductor substrate 1, and the gate insulator film 11 with a thickness of about 10 nm is formed on the well 2 by, for instance, a thermal oxidation method (FIG. 17A).

Next, a phosphorus-doped polysilicon film 5a which will become the third gate, and the silicon nitride film 10a which will become the fifth insulator film are deposited in order (FIG. 17B).

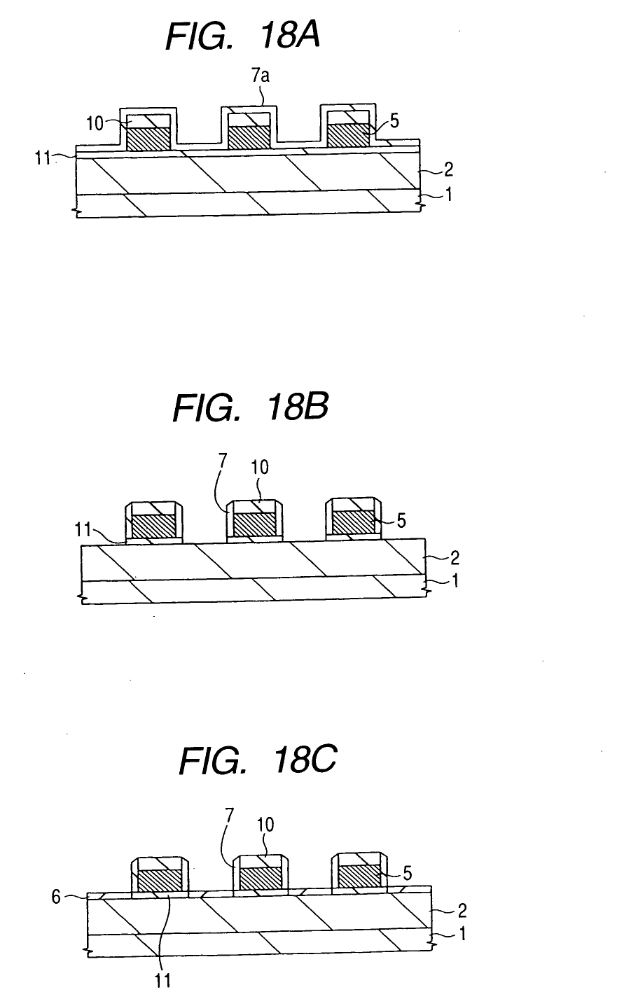

Then, the silicon nitride film 10a and the polysilicon film 5a are patterned by lithography and a dry etching technique. The fifth insulator film 10 and the third gate 5 are formed by this patterning of the silicon nitride film 10a and the polysilicon film 5a, respectively (FIG. 17C). The fifth insulator film 10 and the third gate 5 are patterned in a stripe shape so as to be formed lying along the Y direction. Afterwards, the silicon oxide layer 7a is deposited to avoid the space parts of the aforementioned stripe-shaped pattern from being filled completely (FIG. 18A).

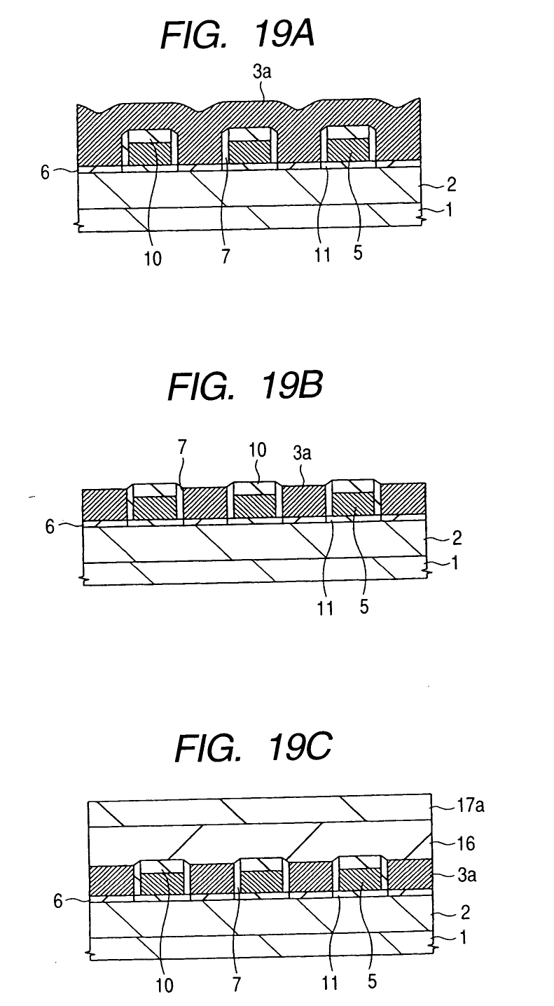

Next, the fourth dielectric layer 7 is formed along the side walls of the fifth insulator film 10 and the third gate 5 by selectively etching back the silicon oxide layer 7a (FIG. 18B). At this time, the gate insulator film 11 is also removed at the space parts of the stripe-shaped pattern formed lying along the aforementioned Y direction. Next, the gate insulator film (first insulator film) 6 is formed by a thermal oxidation or a CVD process (FIG. 18C). Then, the polysilicon film 3a which will become the floating gate is deposited to completely fill the aforementioned space (FIG. 19A). Next, the polysilicon film 3a is partially removed by an etch back technique or by CMP until the top of the fifth insulator film 10 is exposed (FIG. 19B).

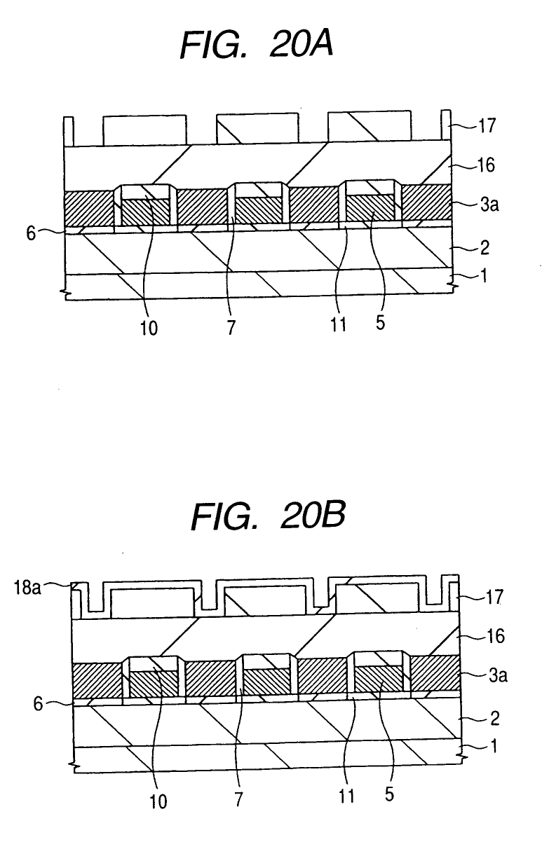

In the next step, the silicon oxide film 16 and the silicon nitride film 17a are deposited in order (FIG. 19C). Then, the silicon nitride film 17a is patterned by lithography and a dry etching technique to form the silicon nitride pattern 17 lying along the Y direction. In this case, the line/space pitch of the silicon nitride film pattern 17 is made to be the same as the line/space pitch of the third gate 5. Moreover, the line parts of the silicon nitride pattern 17 should be made to lie almost on the top of the line parts of the third gate 5 (FIG. 20A). Then, the silicon nitride film 18a is deposited to avoid the space parts of the aforementioned silicon nitride film pattern 17 from being filled completely (FIG. 20B).

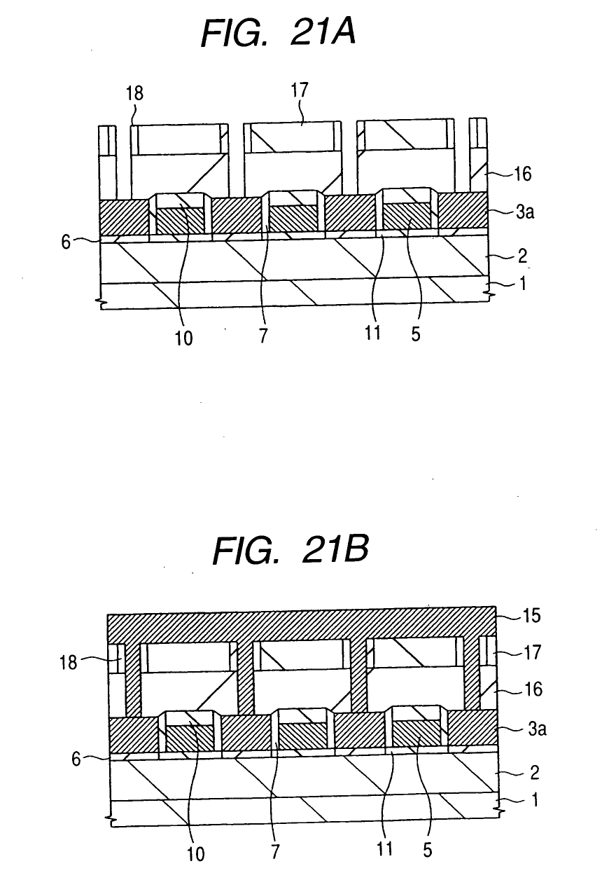

Next, after forming the side walls 18 by etching back the silicon nitride film 18a, the silicon oxide film 16 is dry-etched using the silicon nitride film pattern 17 and the side walls 18 as a mask, resulting in the polysilicon film 3a being exposed (FIG. 21A). Then, the polysilicon film 15 which will become the second layer of the floating gate is deposited to completely fill the space (FIG. 21B).

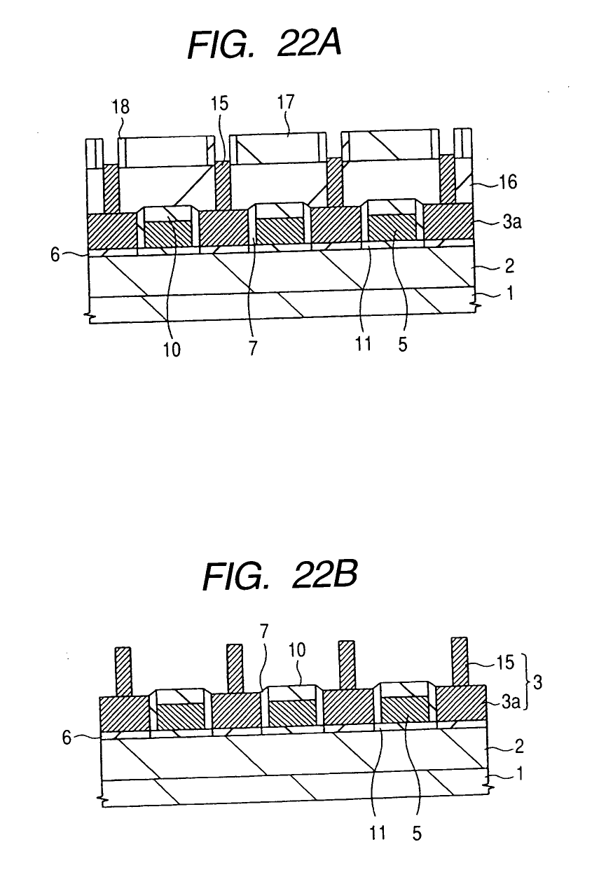

The top of the silicon nitride film pattern 17 and the side wall 18 is exposed by etching back the polysilicon film 15 (FIG. 22A). The silicon nitride film pattern 17 and the side wall 18 are removed, and then the silicon oxide film 16 is removed (FIG. 22B).

According to this process, the polysilicon pattern consisting of a stacked layer of the polysilicon film 3a and the polysilicon film 15 is formed to be a stripe-shaped pattern with an inverse T-shaped cross-section comprising the floating gate 3. In this step, the polysilicon pattern consisting of a stacked layer of the aforementioned polysilicon film 3a and the polysilicon film 15 lies along the Y direction.

In the next step, the same as the aforementioned second embodiment, the second insulator layer 8, electrically insulating the floating gate 3 from the control gate, is formed; the control gate material is deposited; and the control gate (word line WL) is formed by patterning using lithography and a dry etching technique. The control gate 4, the second insulator film 8, and the floating gate 3 are processed in one step by using a stripe-shaped mask pattern lying along the X direction (first direction) while patterning.

Subsequently, the contact hole reaching the control gate 4, the well 2, and the third gate 5, and the contact hole for feeding power to the inversion layer which will become a source and drain located outside of the memory array are formed after forming the interlayer dielectric film. Then, a metallic film is deposited and patterned to be an interconnection, resulting in a memory cell being completed.

In the memory cell of a nonvolatile semiconductor memory fabricated using the above-mentioned process, the part of the floating gate 3 through the control gate 4 and the second insulator film 8 has a smaller dimension than the bottom part of the floating gate 3. Because of this, the opposing area between the floating gates underneath the adjoining word line WL can be reduced while maintaining an adequate area between the floating gate 3 and the control gate 4. That is, maintaining the coupling ratio between the control gate 4 and the floating gate 3 can be compatible with reducing the capacitive coupling between the floating gates 3 underneath the adjoining word line WL. As a result, maintaining the programming/erasing properties can be compatible with reducing the threshold voltage shift caused by changing the adjoining cell conditions.

### Fourth Embodiment

In the aforementioned embodiments, from the first to the third, the control gate material, the interlayer insulator layer between the floating gate and the control gate, and the floating gate material are processed in one step while separating the floating gate in each memory cell. However, it is possible to separate the floating gate in each memory cell without processing in one step as mentioned above.

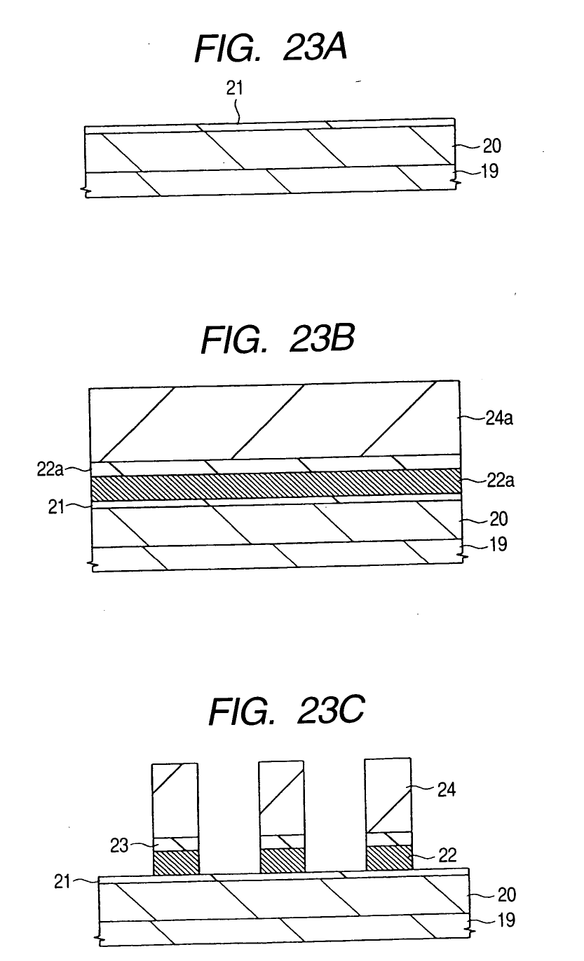

FIGS. 23 to 38 are main cross-sections and main plane diagrams schematically illustrating one example of a nonvolatile semiconductor memory device described in the fourth embodiment of the present invention.

First, a p-well 20 is formed on the semiconductor substrate 19 and the gate insulator film (third insulator film) 21 with a thickness of about 10 nm is formed on the well 20 by, for instance, a thermal oxidation method (FIG. 23A).

Next, the phosphorus-doped polysilicon film 22a which will become the third gate, the silicon oxide film 23a which will become the fifth insulator film, and the silicon nitride film 24a are deposited in order (FIG. 23B).

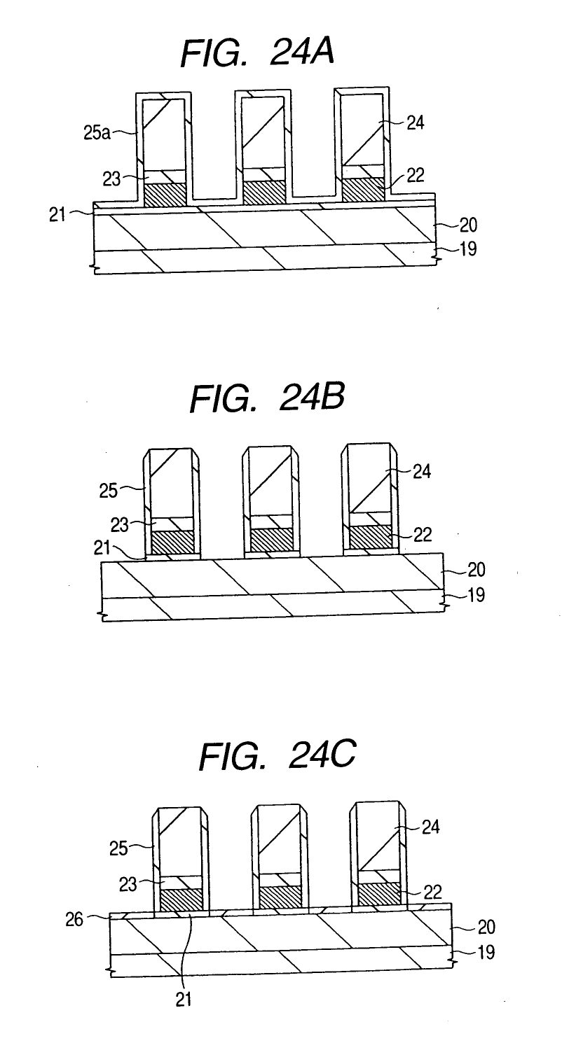

Then, the silicon nitride film 24a, the silicon oxide film 23a, and the polysilicon film 22a are patterned by lithography and a dry etching technique. The silicon nitride film pattern 24, the fifth insulator film 23 and the third gate 22 are formed by this patterning of the silicon nitride film 24a, the silicon oxide film 23a and the polysilicon film 22a, respectively (FIG. 23C). The silicon nitride film pattern 24, the fifth insulator film 23 and the third gate 22 are patterned in a stripe shape so as to be formed lying along the Y direction. Afterwards, the silicon oxide layer 25a is deposited to avoid the space parts of the stripe-shaped pattern from being filled completely (FIG. 24A).

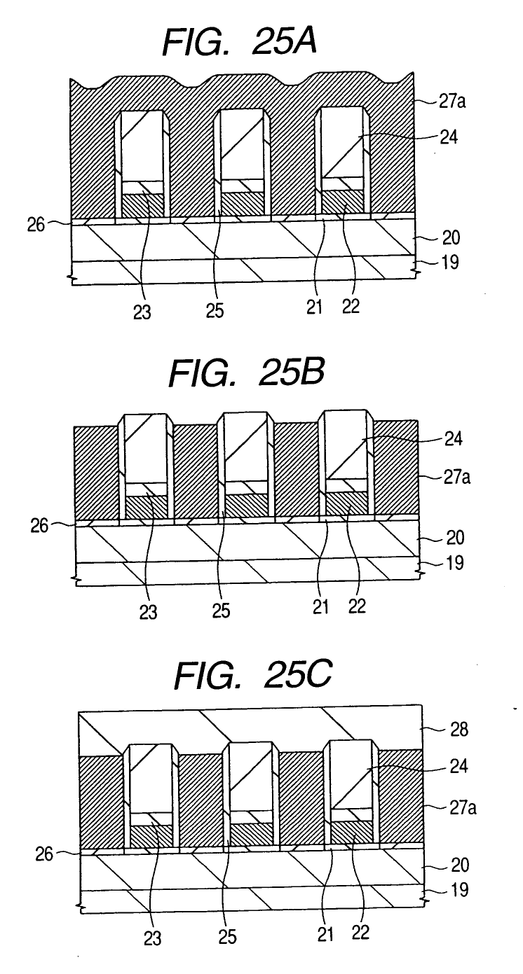

Next, the fourth insulator layer 25 is formed along the side walls of the silicon nitride film pattern 24, the fifth insulator film 23 and the third gate 22 by selectively etching back the silicon oxide layer 25a (FIG. 24B). At this time, the gate insulator film 21 is also removed at the space parts of the stripe-shaped pattern formed lying along the aforementioned Y direction. Next, the gate insulator film (first insulator film) 26 is formed by a thermal oxidation or a CVD method (FIG. 24C). Then, the polysilicon film 27a which will become the floating gate is deposited to completely fill the aforementioned space (FIG. 25A).

The polysilicon film 27a is partially removed by an etch back technique or by CMP until the top of the silicon nitride film pattern 24 is exposed (FIG. 25B). Then, the silicon nitride film 28 is deposited (FIG. 25C).

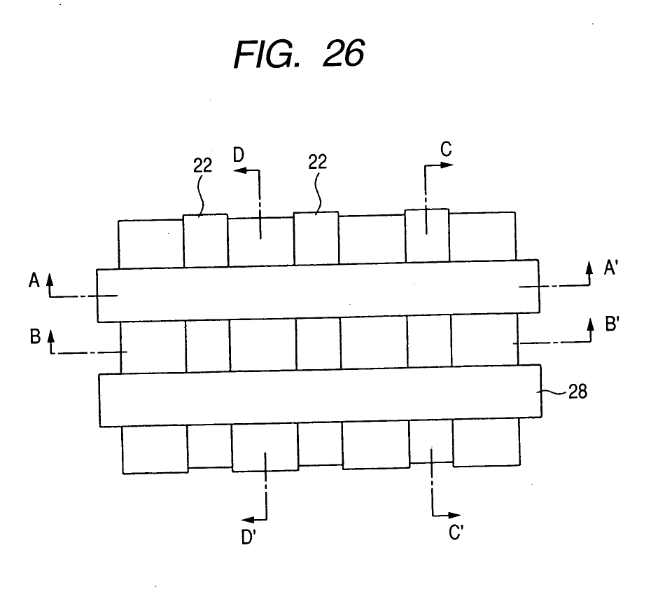

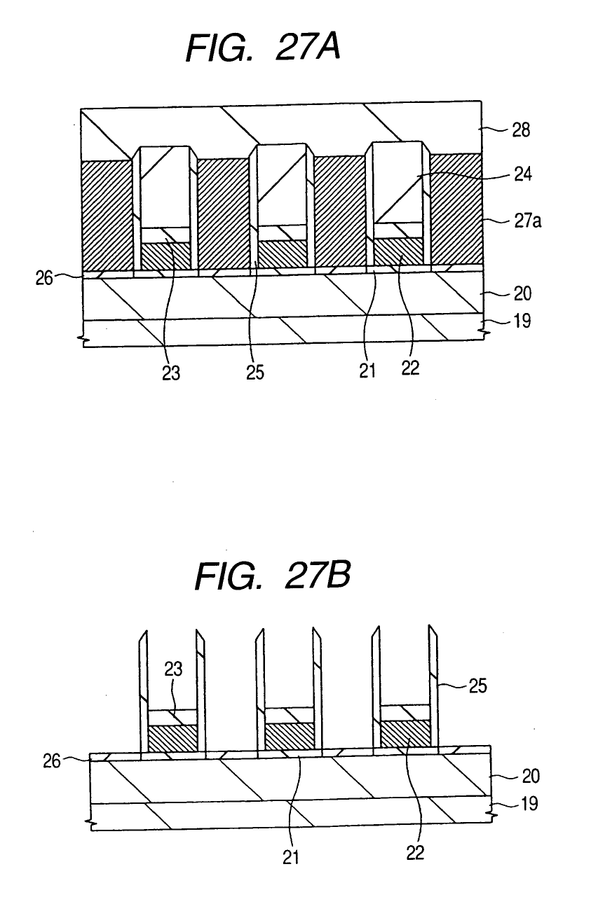

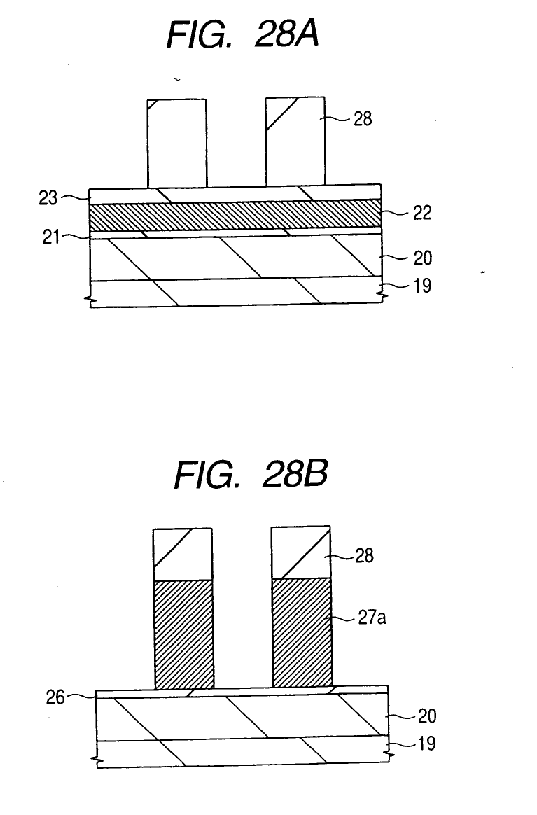

Moreover, the silicon nitride film 28, the silicon nitride film pattern 24, and the polysilicon film 27a are etched in order, using a stripe-shaped mask pattern lying along the direction (X direction) perpendicular to the Y direction. FIG. 26 is a main plane diagram illustrating this step. Furthermore, the line cross-section A-A′ and the line cross-section B-B′ of FIG. 26 become FIGS. 27A and 27B, respectively, after pattering the word line. And, the line cross-section C-C′ and the line cross-section D-D′ of FIG. 26 become FIGS. 28A and 28B, respectively, after pattering the word line. The third gate 22 is not cut off and left lying along the Y direction. Moreover, the polysilicon film 27a which will become the floating gate is separated in each memory cell at this stage.

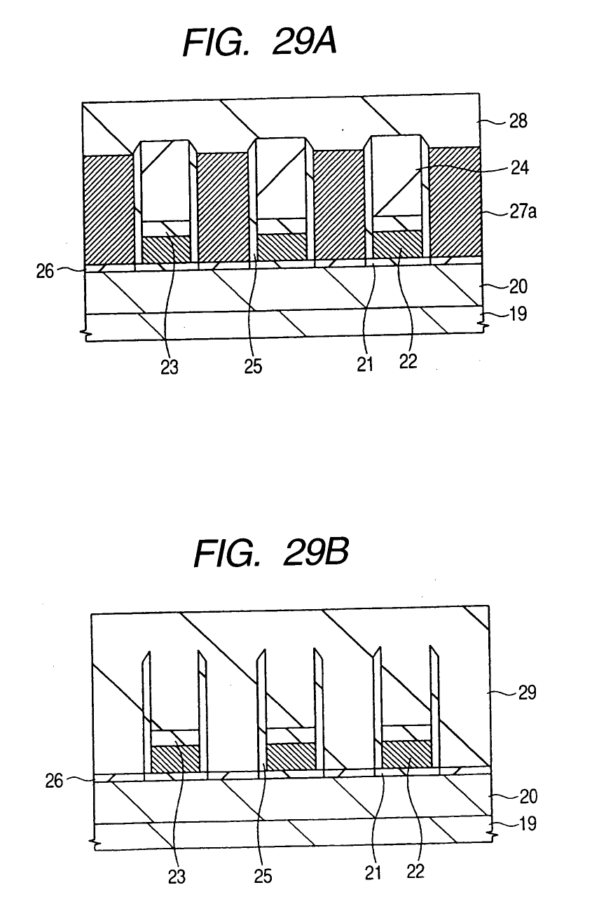

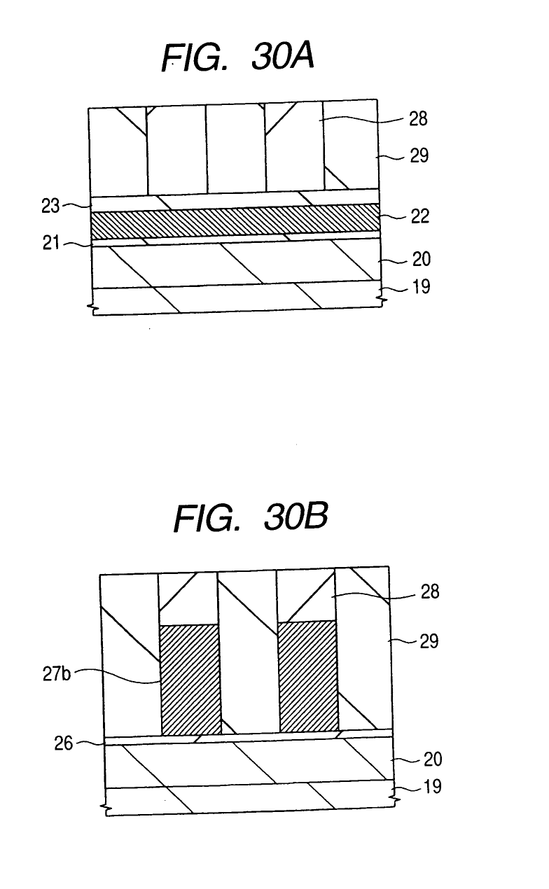

Next, the silicon oxide film 29 is deposited to completely fill the space parts of the pattern consisting of the silicon nitride film 28, the silicon nitride film pattern 24, and the polysilicon film 27a. The aforementioned line cross-section A-A′ and the line cross-section B-B′ of FIG. 29 become FIGS. 29A and 29B, respectively, and the line cross-section C-C′ and the line cross-section D-D′ become FIGS. 30A and 30B, respectively, according to the process in which a part of the silicon oxide film 29 is removed by an etch back technique or by CMP to expose the top of the silicon nitride film 28.

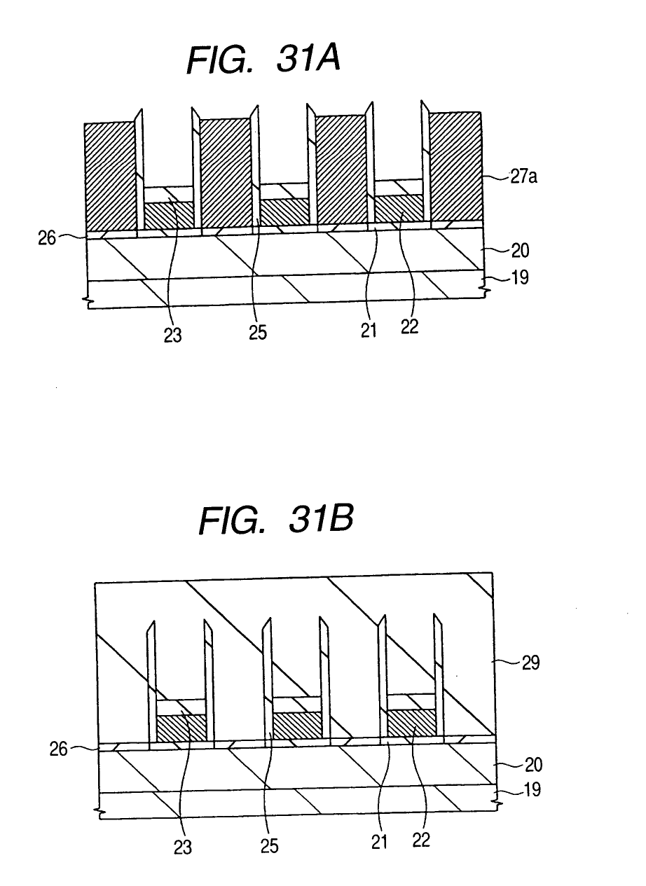

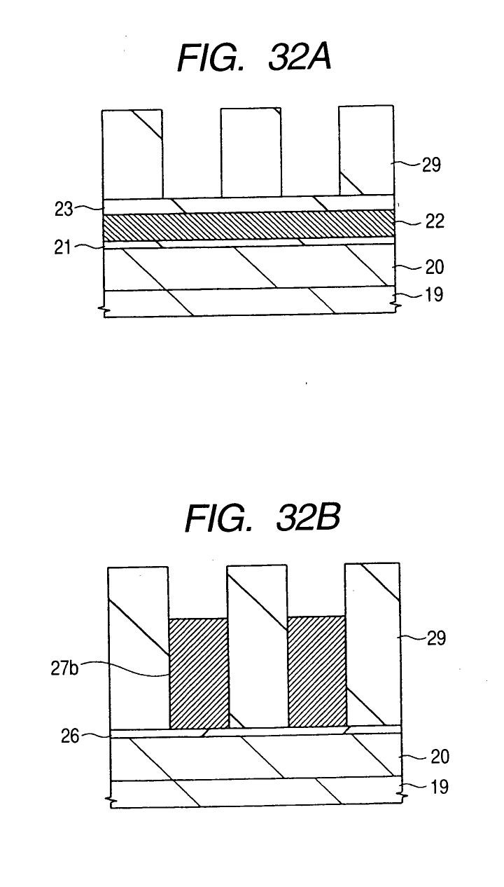

Next, the silicon nitride film 28 and the silicon nitride film pattern 24 are removed by a dry etching technique using the silicon oxide film 29 as a mask. The line cross-section A-A′ and the line cross-section B-B′ of FIG. 26 become FIGS. 31A and 31B, respectively. And, the line cross-section C-C′ and the line cross-section D-D′ of FIG. 26 become FIGS. 32A and 32B, respectively.

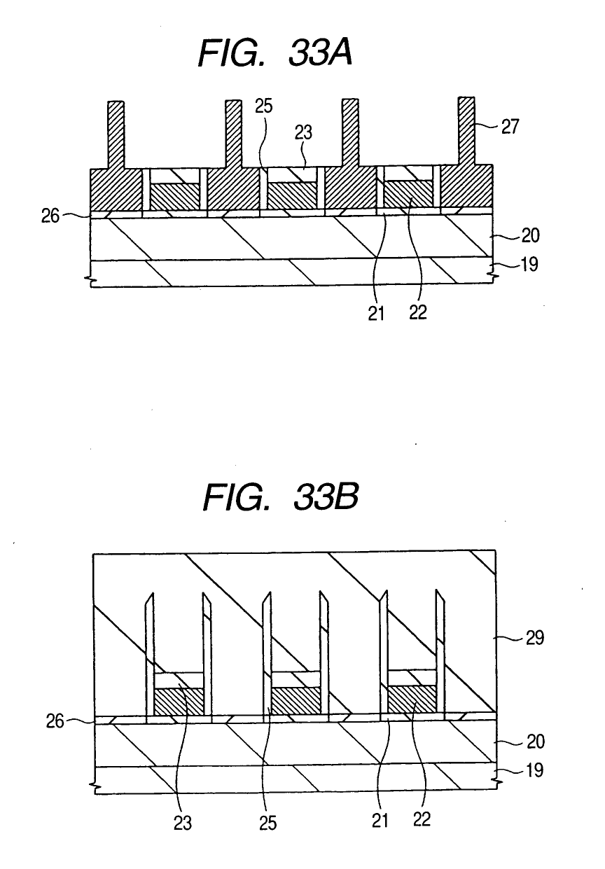

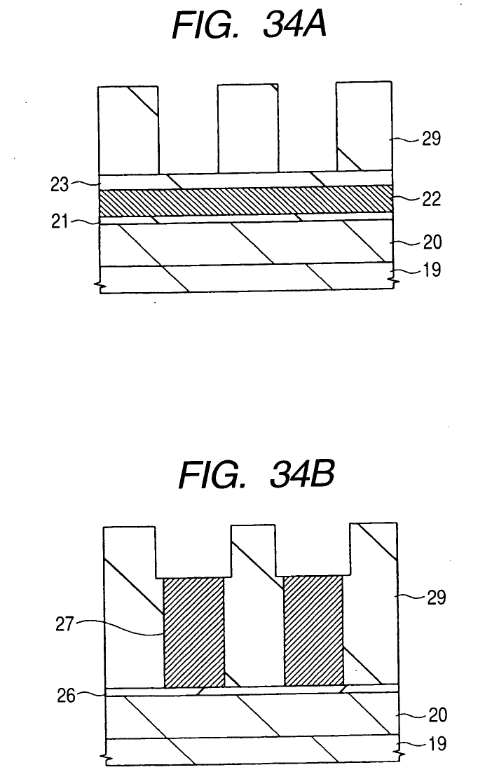

Next, the polysilicon film 27a is etched by an isotropic etching technique after removing a part of the fourth insulator film 25 on the side walls of the polysilicon film 27a by an isotropic etching technique (for instance, a wet etching technique). The line cross-section A-A′ and the line cross-section B-B′ of aforementioned FIG. 26 become FIGS. 33A and 33B, respectively. And, the line cross-section C-C′ and the line cross-section D-D′ of FIG. 26 become FIGS. 34A and 34B, respectively. The floating gate (first gate) 27 is formed to become inverse T-shaped as shown in FIG. 33A.

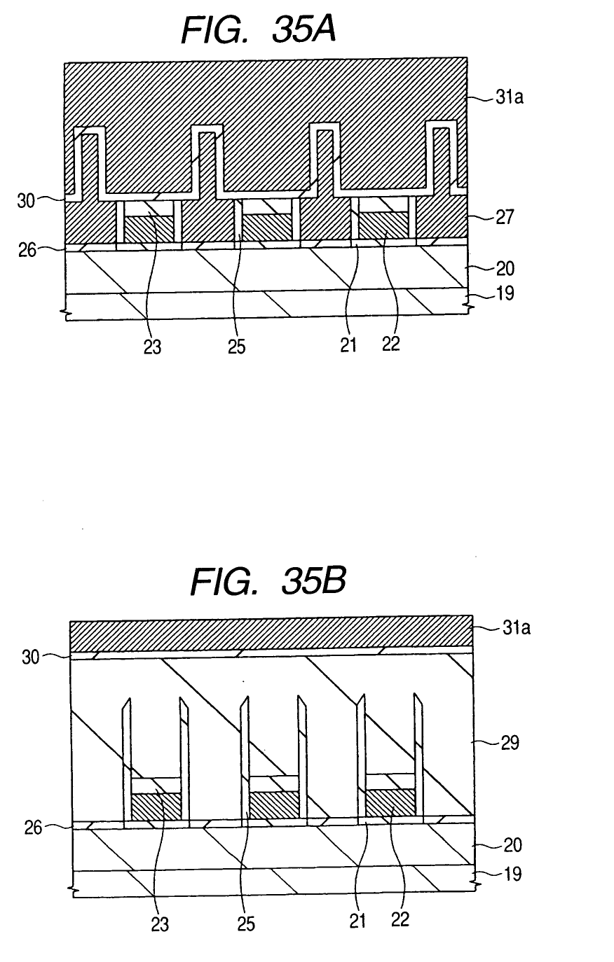

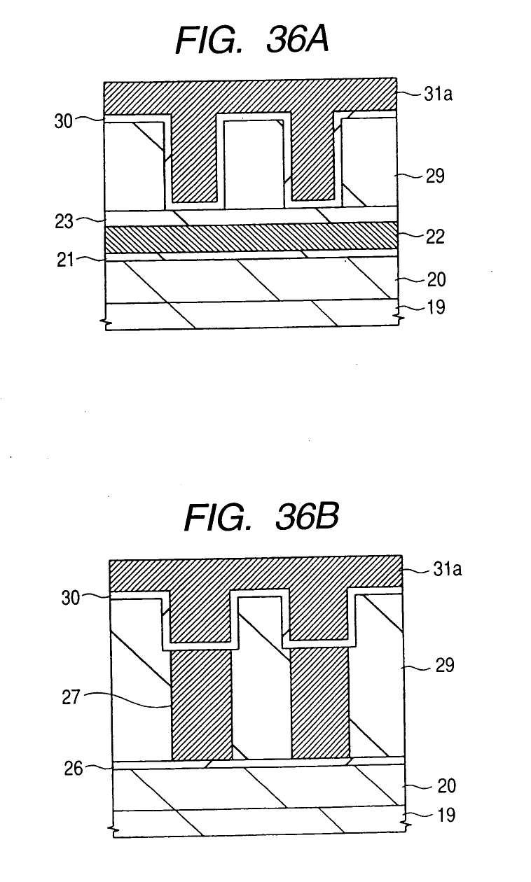

Next, the second insulator film 30, which insulates the gap between the floating gate 27 and the control gate, and the control gate material 31a are deposited in order. The line cross-section A-A′ and the line cross-section B-B′ of aforementioned FIG. 26 become FIGS. 35A and 35B, respectively. And, the line cross-section C-C′ and the line cross-section D-D′ of FIG. 26 become FIGS. 36A and 36B, respectively.

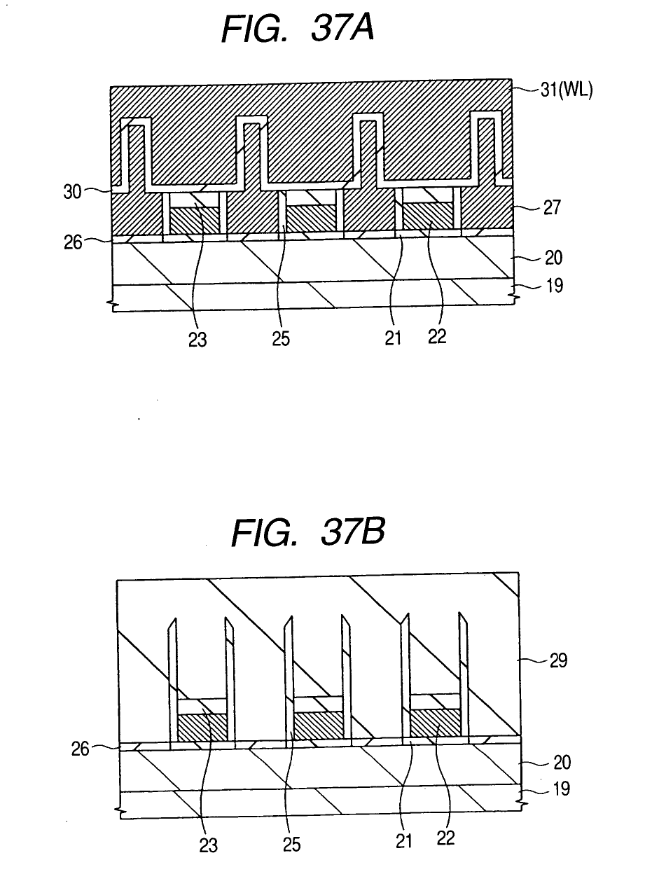

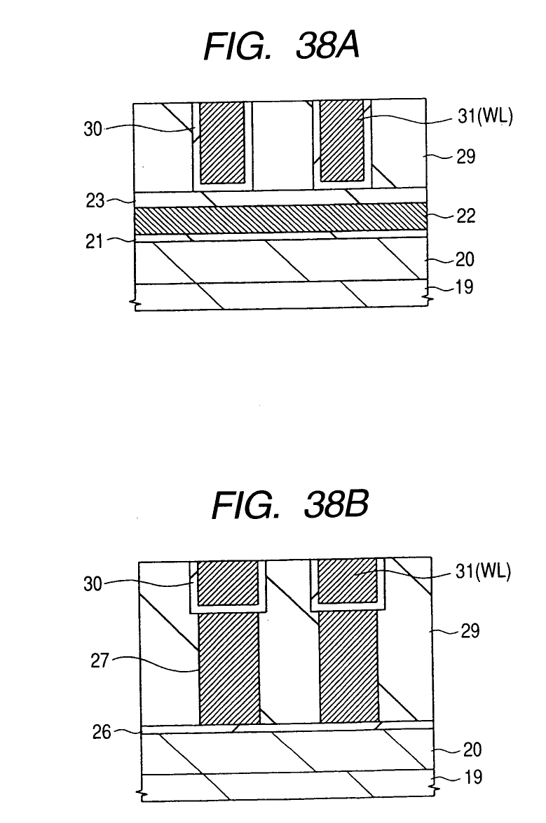

In the next step, the control gate material 31a is removed by CMP or an etch back technique until the top of the silicon oxide film 29 is exposed. The line cross-section A-A′ and the line cross-section B-B′ of aforementioned FIG. 26 become FIGS. 37A and 37B, respectively. And, the line cross-section C-C′ and the line cross-section D-D′ of FIG. 26 become FIGS. 38A and 38B, respectively.

In this stage, the control gate (second gate) 31 (word line WL) lying along the X direction (first direction) is formed. The gap of the adjoining word lines WL is insulated by the silicon oxide film 29. Furthermore, the control gate 31 is not necessary to be processed in one step because the floating gate 27 is separated in each memory cell in the stage of aforementioned FIG. 26.

Subsequently, the contact hole reaching the control gate 31, the well 20, and the third gate 22, and the contact hole for feeding power to the inversion layer which will become a source and drain located outside of the memory array are formed after forming the interlayer dielectric film. Then, a metallic film is deposited and patterned to be an interconnection, resulting in a memory cell being completed.

In the memory cell of a nonvolatile semiconductor memory fabricated using the above-mentioned process, the part of the floating gate 27 through the control gate 31 and the second insulator film 30 has a smaller dimension than the bottom part of the floating gate 27. Because of this, the opposing area between the floating gates 27 underneath the adjoining word line WL can be reduced while maintaining an adequate area between the floating gate 27 and the control gate 31. That is, maintaining the coupling ratio between the control gate 31 and the floating gate 27 can be compatible with reducing the capacitive coupling between the floating gates 27 underneath the adjoining word line WL. As a result, maintaining the programming/erasing properties can be compatible with reducing the threshold voltage shift caused by changing the adjoining cell conditions.

### Fifth Embodiment

In the fifth embodiment, an example of a so-called NAND-type flash memory will be described.

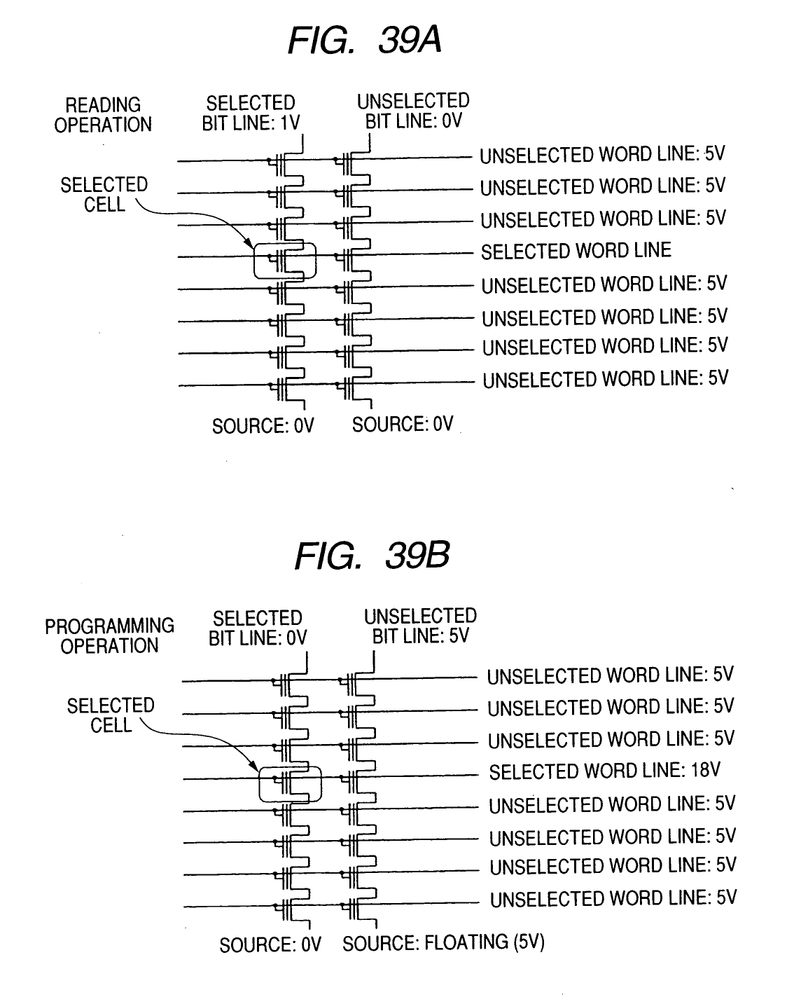

FIG. 39 is a read and program operation of a NAND-type flash memory.

As described in FIG. 39a, 1 V is biased to the selected bit line and 0 V is biased to the source while reading. A voltage of about 5 V is biased to the word line in the cell underneath the unselected word line connected to the selected bit line because it is necessary that the channel must be ON independent of the programming condition to determine the selected cell condition. According to this, the threshold voltage of the selected cell can be determined.

On the other hand, 1 V is biased to the selected bit line and 0 V is biased to the unselected bit line while programming. Programming is carried out by the tunnel current from the silicon substrate to the floating gate, which is generated by biasing a high voltage of about 18 V to the selected word line.

Programming is prohibited by biasing about 5 V to the bit line in the unselected bit line to relieve the voltage difference between the channel and the floating gate. Therefore, it is necessary that the channel underneath the unselected word line is ON independent of the programming condition of the cell, and that a voltage of about 8 V is biased to the unselected word line.

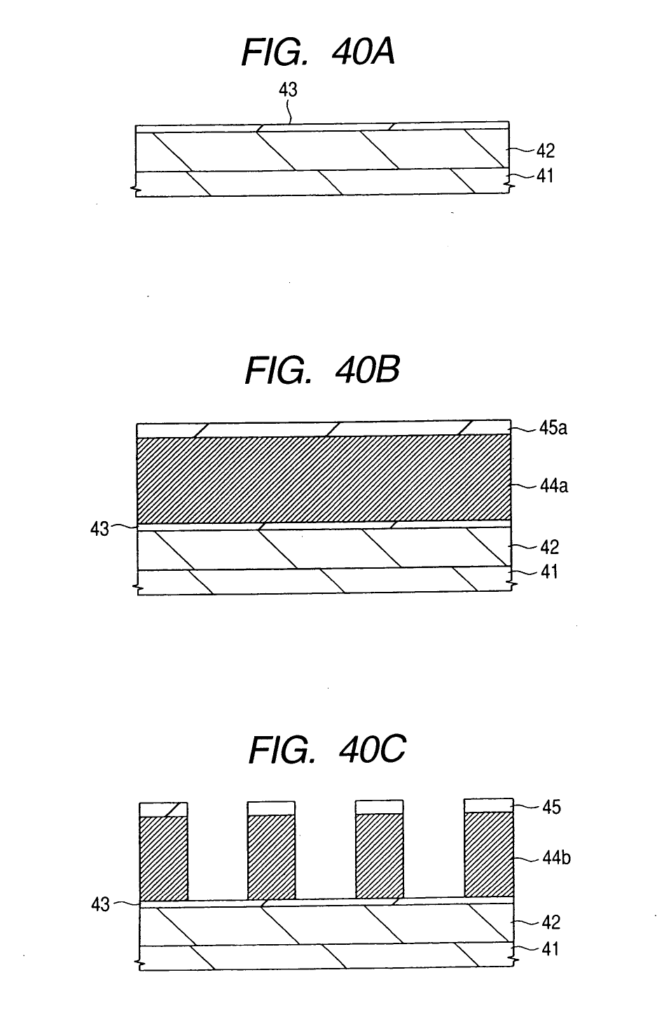

FIGS. 40 to 45 are main cross-sections and main plane diagrams schematically illustrating one example of a nonvolatile semiconductor memory device described in the fifth embodiment of the present invention.

First, a p-well 42 is formed on the silicon substrate 41; the gate insulator film (first insulator film) 43 is formed on it by, for instance, a thermal oxidation method (FIG. 40A); and the polysilicon film 44a, which will become the floating gate, and the silicon nitride film 45a are deposited in order on top of them by, for instance, a CVD method (FIG. 40B).

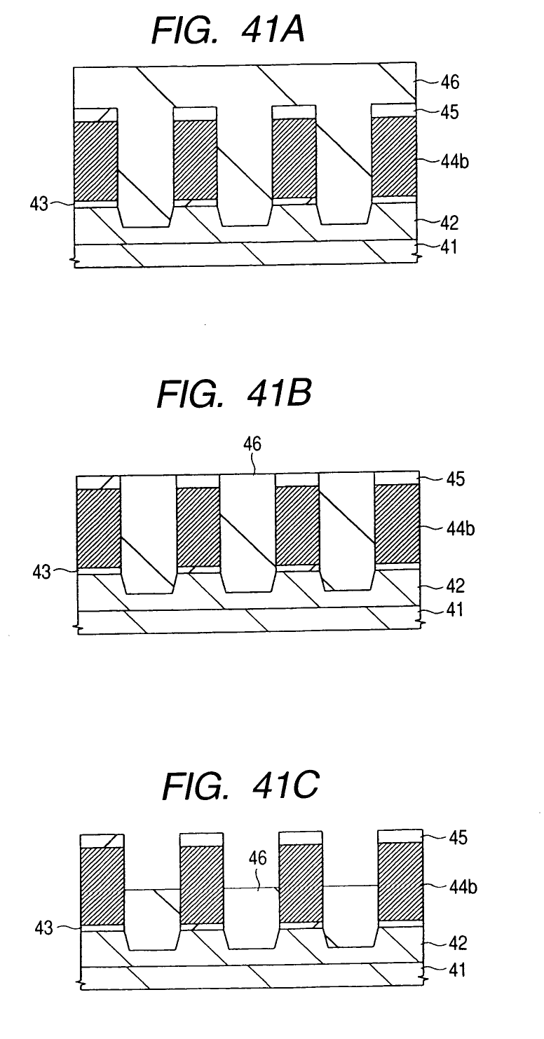

Next, the silicon nitride film 45a and the polysilicon film 44a are patterned in a strip shape by lithography and a dry etching technique to form the silicon nitride film pattern 45 and the polysilicon film pattern 44b (FIG. 40C). Then, after etching the gate insulator film 43 and the silicon substrate 41 using the silicon nitride film pattern 45 and the polysilicon film pattern 44b as a mask, the silicon oxide film 46 is deposited to completely fill the silicon nitride film pattern 45 and the gaps (FIG. 41A). A part of the silicon oxide film 46 is removed by CMP to expose the surface of the silicon nitride film pattern 45 (FIG. 41B). Moreover, the side walls of the polysilicon film pattern 44b are exposed by etching back the silicon oxide film 46 (FIG. 41C).

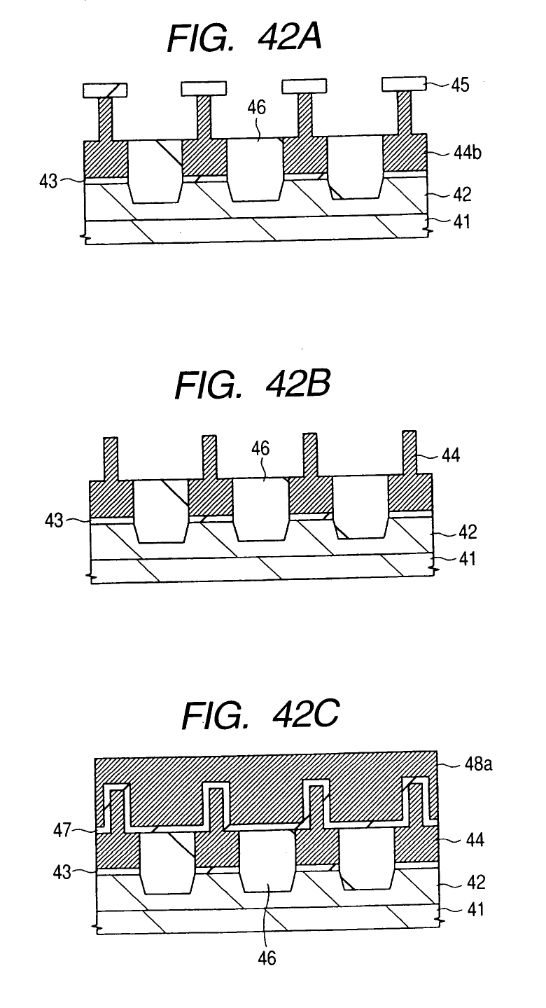

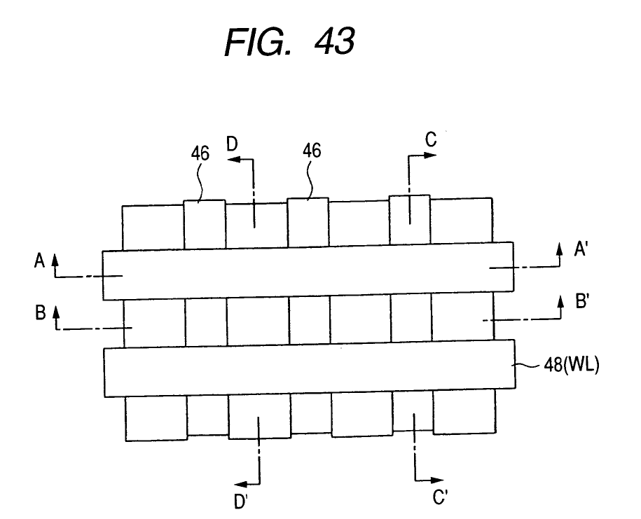

In the next step, the polysilicon film pattern 44b is isotropically etched (FIG. 42A). Then, the silicon nitride film pattern 45 is removed by a dry etching or a wet etching technique (FIG. 42B). According to this process, the polysilicon pattern 44b is formed to be a stripe-shaped pattern with an inverse T-shaped cross-section, consisting of the floating gate (first gate) 44. Next the second insulator film 47 electrically insulating the floating gate 44 from the control gate is formed. For instance, a silicon oxide film or a stacked film of silicon oxide film/silicon nitride film/silicon oxide film can be used for the second insulator film 47. Then, the control gate material 48a is deposited. For instance, a polysilicon film and a stacked film of a tungsten nitride film and a tungsten film, a so-called polymetal film, can be used for the control gate material (FIG. 42C). The control gate (second gate) 48 (word line WL) is formed by patterning using lithography and a dry etching technique (FIG. 43). The control gate 48, the second insulator film 47, and the floating gate 44 are processed in one step while patterning using a stripe-shaped mask pattern lying along the X direction.

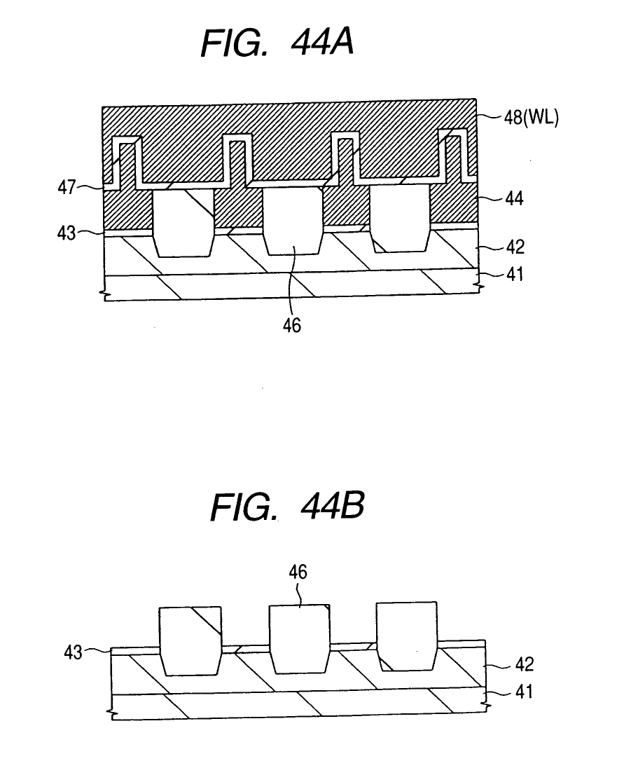

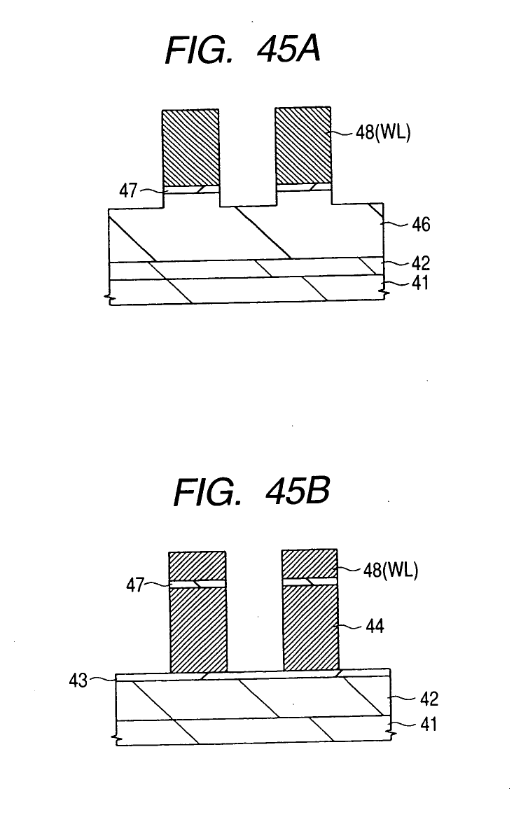

The line cross-section A-A′ and the line cross-section B-B′ of aforementioned FIG. 43 become FIGS. 44A and 44B, respectively, and the line cross-section C-C′ and the line cross-section D-D′ of FIG. 43 become FIGS. 45A and 45B, respectively.

Subsequently, the contact holes reaching the control gate 48 and the well 42, and the contact holes for feeding power to the source and drain diffusion layers located outside of the memory array are formed after forming the interlayer dielectric film. Then, a metallic film is deposited and patterned to be an interconnection, resulting in a memory cell being completed.

In the memory cell of a nonvolatile semiconductor memory fabricated using the above-mentioned process, the part of the floating gate 44 through the control gate 48 and the second insulator film 47 has a smaller dimension than the bottom part of the floating gate 44. Because of this, the opposing area between the floating gates 44 underneath the adjoining word line WL can be reduced while maintaining an adequate area between the floating gate 44 and the control gate 48. That is, maintaining the coupling ratio between the control gate 48 and the floating gate 44 can be compatible with reducing the capacitive coupling between the floating gates 44 underneath the adjoining word line WL. As a result, maintaining the programming/erasing properties can be compatible with reducing the threshold voltage shift caused by changing the adjoining cell conditions.

### Sixth Embodiment

In the aforementioned fifth embodiment, the floating gate was formed in an inverse T-shape by an isotropic etching technique after forming the floating gate in a stripe-shaped pattern, but it is also possible to make the floating gate in an inverse T-shape by forming the floating gate by two layers of polysilicon.

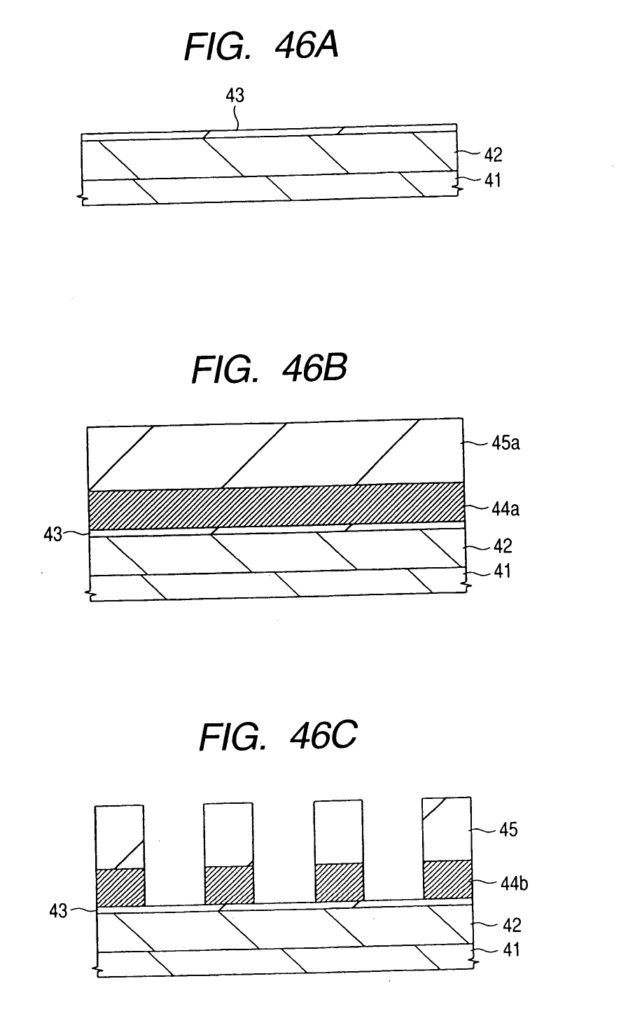

FIGS. 46 to 49 are main plane diagrams schematically illustrating one example of a nonvolatile semiconductor memory device described in the sixth embodiment of the present invention.

First, a p-well 42 is formed on the silicon substrate 41; the gate insulator film 43 is formed on it by, for instance, a thermal oxidation method (FIG. 46A); and the polysilicon film 44a, which will become the floating gate, and the silicon nitride film 45a are deposited in order on top of them by, for instance, a CVD method (FIG. 46B).

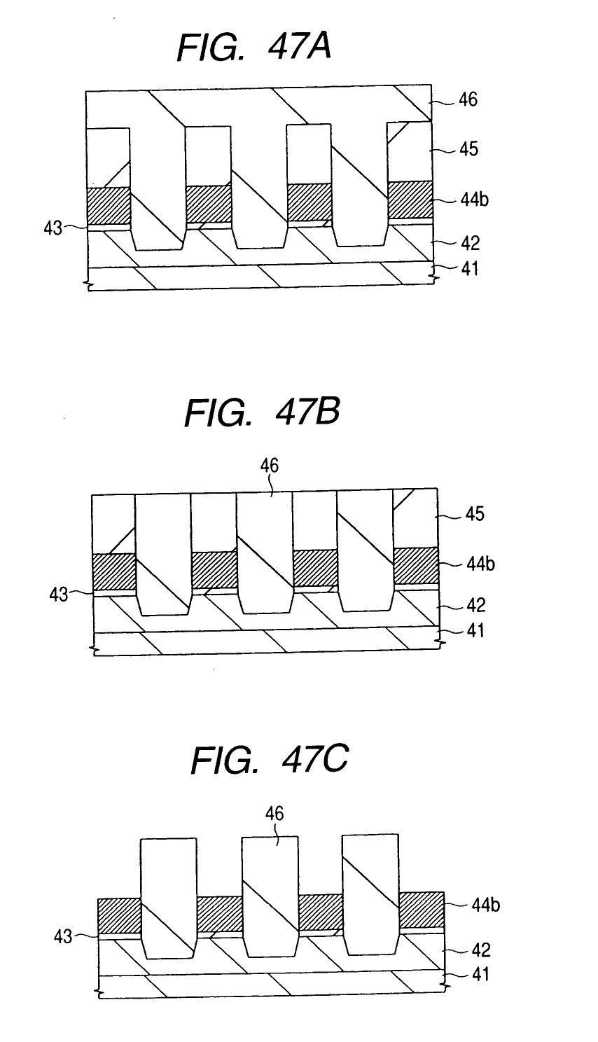

Next, the silicon nitride film 45a and the polysilicon film 44a are patterned in a strip shape by lithography and a dry etching technique to form the silicon nitride film pattern 45 and the polysilicon film pattern 44b (FIG. 46C). Then, after etching the gate insulator film 43 and the silicon substrate 41 in order, using the silicon nitride film pattern 45 and the polysilicon film pattern 44b as a mask, the silicon oxide film 46 is deposited to completely fill the silicon nitride film pattern 45 and the gaps (FIG. 47A). A part of the silicon oxide film 46 is removed by CMP to expose the surface of the silicon nitride film pattern 45 (FIG. 47B). Moreover, the surface of the polysilicon film pattern 44b is exposed by dry-etching the silicon nitride film pattern 45 (FIG. 47C).

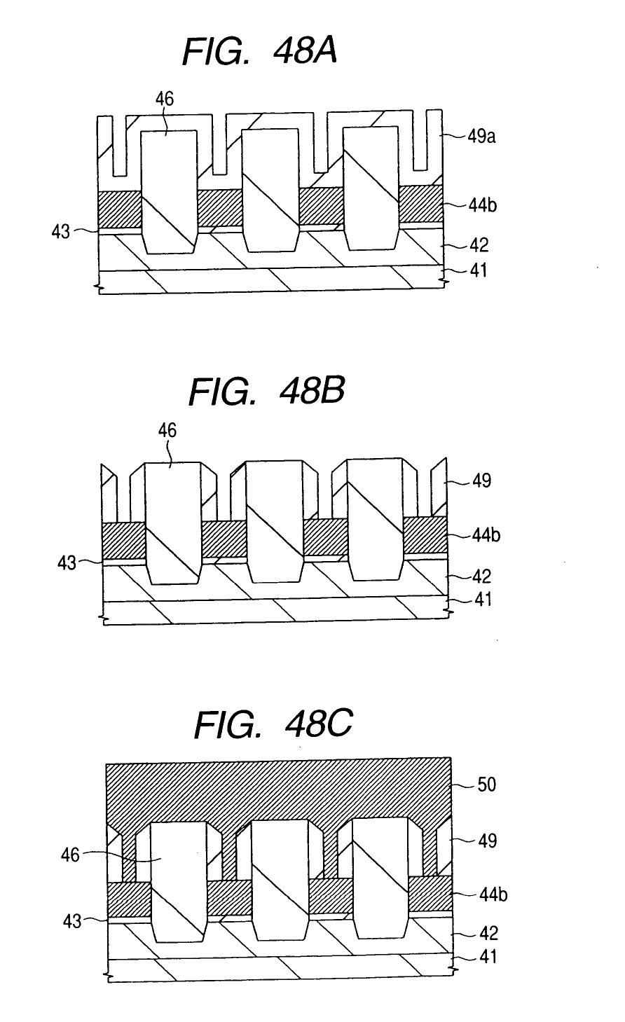

Afterwards, the silicon oxide layer 49a is deposited to avoid the space parts formed by removing the silicon nitride film pattern 45 from being filled completely (FIG. 48A). Next, the side wall 49 is formed by etching back the silicon oxide film 49a (FIG. 48B). Then, the polysilicon film 50 which will become the floating gate (second layer) is deposited (FIG. 48C).

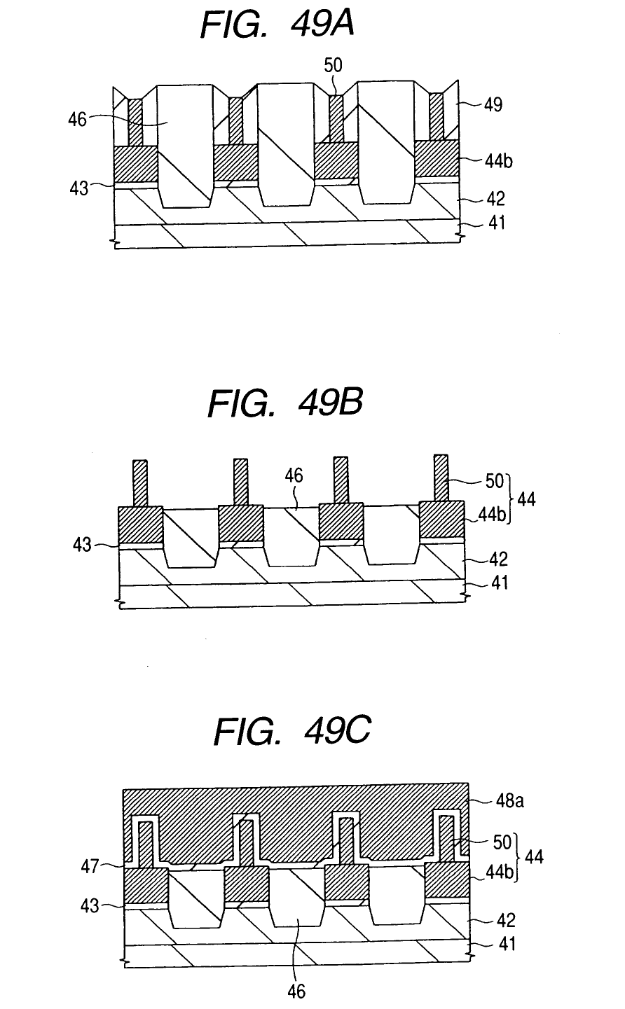

A part of the polysilicon film 50 is removed by an etch back technique and by CMP to expose the surface of the silicon oxide film 46 (FIG. 49A). Next, after removing a part of the silicon oxide film 46 and the side wall 49 by etching back, the parts which are not covered by the polysilicon film 50 are exposed in the side wall of the polysilicon film 50 and the top part of the polysilicon film pattern 44b (FIG. 49B). According to this process, the stacked film of the polysilicon pattern 44b and the polysilicon film 50 is formed to be a stripe-shaped pattern with an inverse T-shaped cross-section, comprising the floating gate 44.

Next the second insulator film 47 electrically insulating the floating gate 44 from the control gate is formed. For instance, a silicon oxide film or a stacked film of silicon oxide film/silicon nitride film/silicon oxide film can be used for the second insulator film 47. Then, the control gate material 48a is deposited. For instance, a polysilicon film and a stacked film of a tungsten nitride film and a tungsten film, a so-called polymetal film, can be used for the control gate material 48a (FIG. 49C).

After that, the same as the aforementioned fifth embodiment, the control gate 48 (word line WL) is formed by patterning using lithography and a dry etching technique. The control gate 48, the second insulator film 47, and the floating gate 44 are processed in one step while patterning using a stripe-shaped mask pattern lying along the X direction.

Subsequently, the contact holes reaching the control gate 48 and the well 20, and the contact holes for feeding power to the source and drain diffusion layers located outside of the memory array are formed after forming the interlayer dielectric film. Then, a metallic film is deposited and patterned to be an interconnection, resulting in a memory cell being completed.

In the memory cell of a nonvolatile semiconductor memory fabricated using the above-mentioned process, the part of the floating gate 44 through the control gate 48 and the second insulator film 47 has a smaller dimension than the bottom part of the floating gate 44. Because of this, the opposing area between the floating gates 44 underneath the adjoining word line WL can be reduced while maintaining an adequate area between the floating gate 44 and the control gate 48. That is, maintaining the coupling ratio between the control gate 48 and the floating gate 44 can be compatible with reducing the capacitive coupling between the floating gates 44 underneath the adjoining word line WL. As a result, maintaining the programming/erasing properties can be compatible with reducing the threshold voltage shift caused by changing the adjoining cell conditions.

### Seventh Embodiment

In the aforementioned fifth and sixth embodiments, the control gate material, the interlayer insulator layer (second insulator film) between the floating gate and the control gate, and the floating gate material are processed in one step while separating the floating gate in each memory cell. However, it is possible to separate the floating gate in each memory cell without processing in one step as mentioned above.

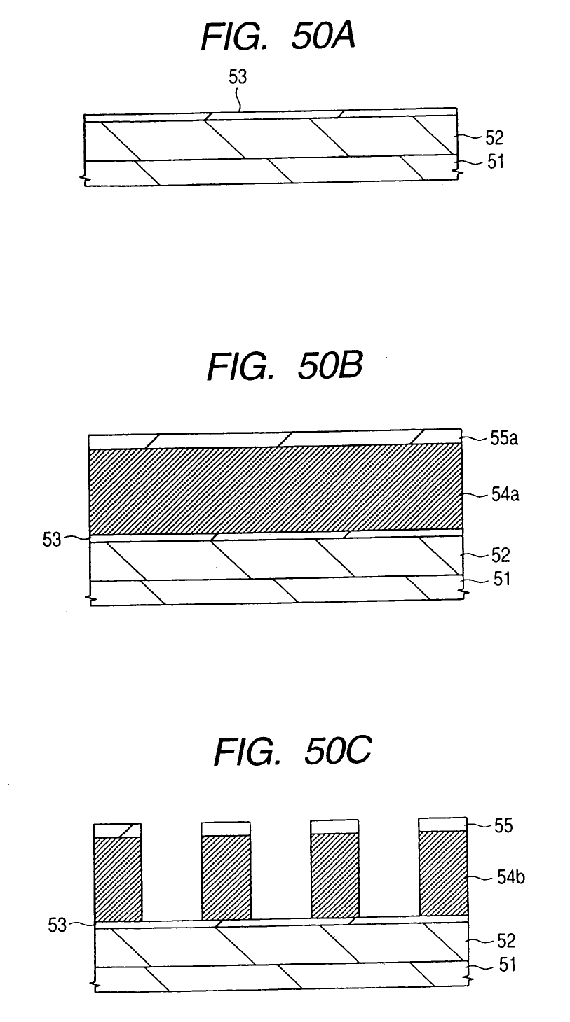

FIGS. 50 to 63 are main plane diagrams schematically illustrating one example of a nonvolatile semiconductor memory device described in the seventh embodiment of the present invention.

First, a p-well 52 is formed on the silicon substrate 51; the gate insulator film (first insulator film) 53 is formed on it by, for instance, a thermal oxidation method (FIG. 50A); and the polysilicon film 54a, which will become the floating gate, and the silicon nitride film 55a are deposited in order, on top of them by, for instance, a CVD method (FIG. 50B). Next, the silicon nitride film 55a and the polysilicon film 54a are patterned in a strip shape by lithography and a dry etching technique to form the silicon nitride film pattern 55 and the polysilicon film pattern 54b (FIG. 50C).

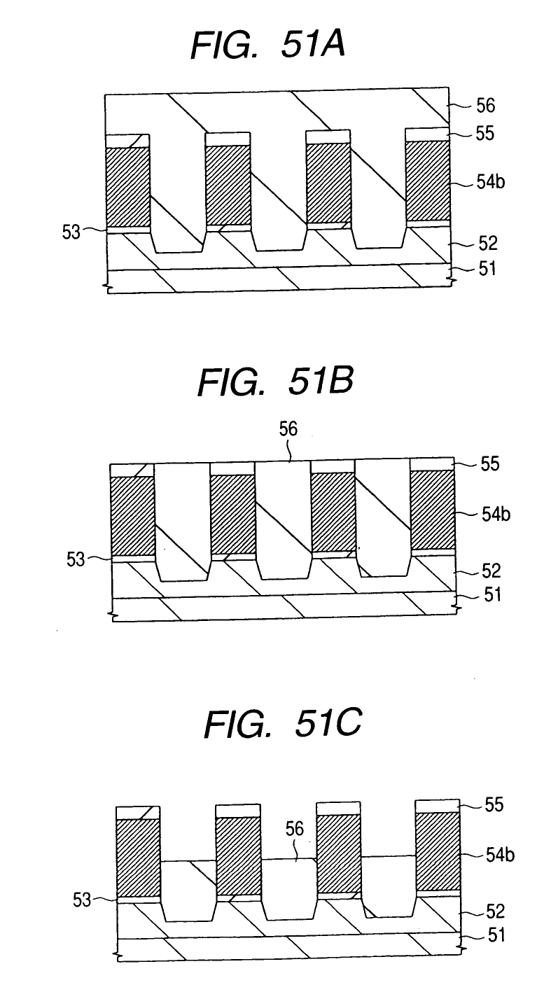

Then, after etching the gate insulator film 53 and the silicon substrate 51 in order, using the polysilicon film pattern 54b and the silicon nitride film pattern 55 as a mask, the silicon oxide film 56 is deposited to completely fill the silicon nitride film pattern 55 and the gaps (FIG. 51A). A part of the silicon oxide film 56 is removed by CMP to expose the surface of the silicon nitride film pattern 55 (FIG. 51B). Moreover, a part of the side of the polysilicon film pattern 54b is exposed by dry-etching the silicon oxide film 56 (FIG. 51C).

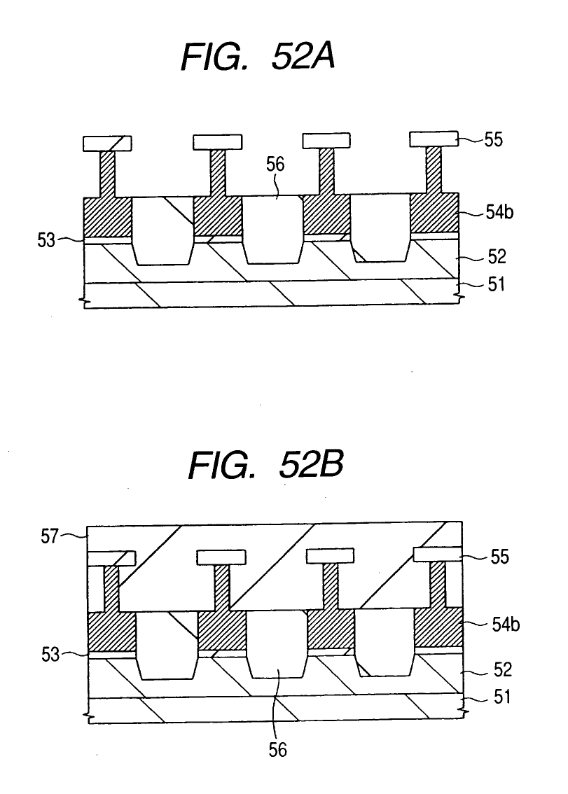

Next, isotropic etching is carried out on the polysilicon film pattern 54b (FIG. 52A). As a result, the cross-section of the polysilicon film pattern 54b becomes an inverse T-shaped stripe pattern.

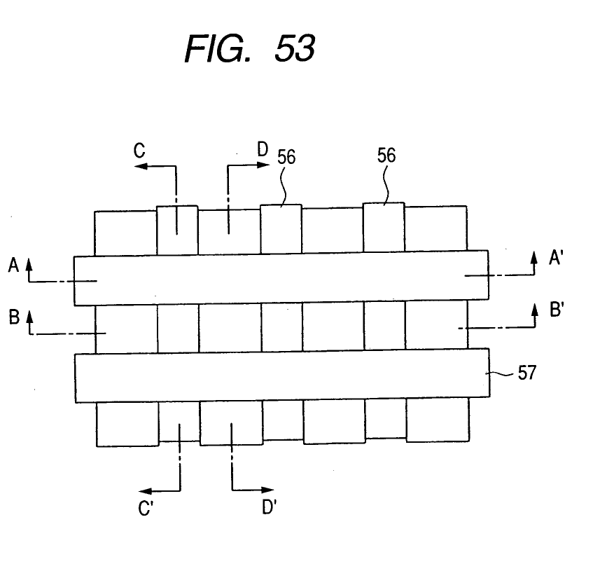

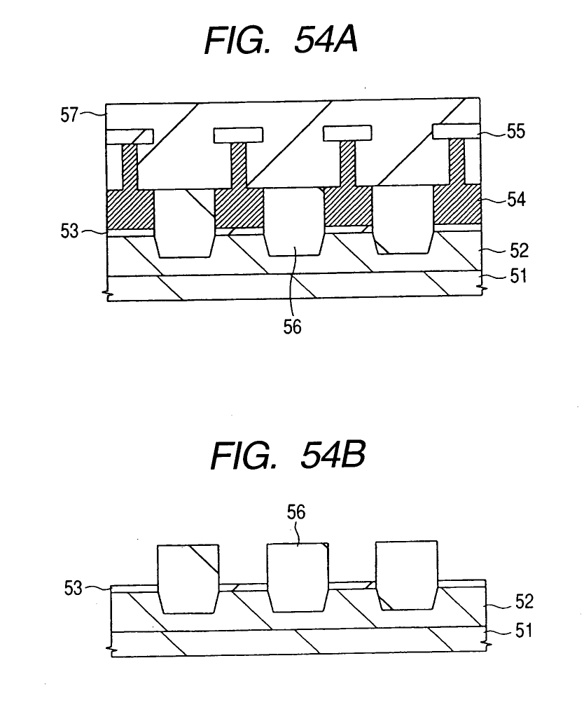

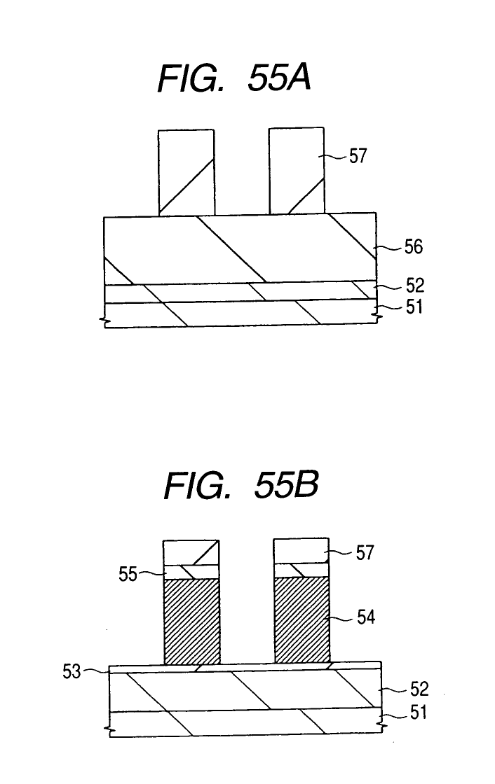

Then, the silicon nitride film 57 is deposited (FIG. 52B). Next, the silicon nitride film 57, the silicon nitride film pattern 55, and the polysilicon film pattern 54b are etched in order, using a line/space stripe-shaped mask along a direction perpendicular to the stripe of the stripe-shaped polysilicon film pattern 54b. FIG. 53 is a main plane diagram illustrating this step. Moreover, the line cross-section A-A′ and the line cross-section B-B′ of aforementioned FIG. 53 become FIGS. 54A and 54B, respectively. And, the line cross-section C-C′ and the line cross-section D-D′ of FIG. 53 become FIGS. 55A and 55B, respectively. The stripe-shaped polysilicon film pattern 54b is separated in each memory cell at this stage to become the floating gate (first gate) 54.

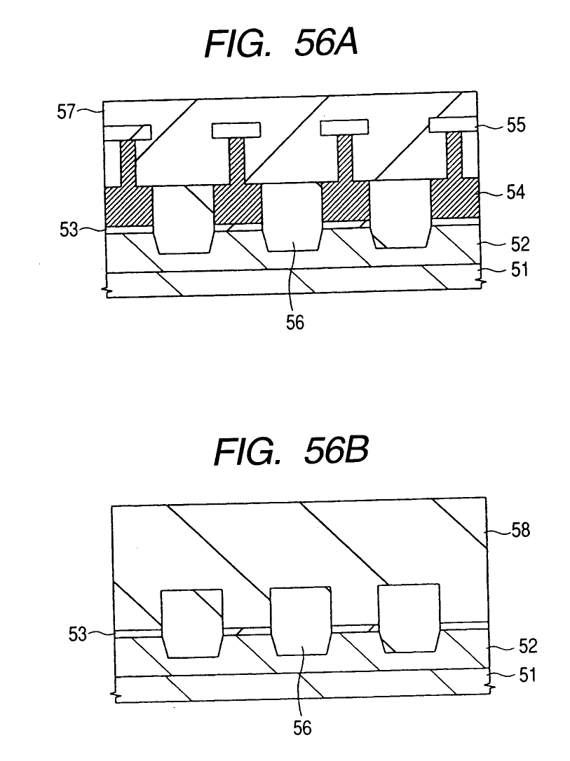

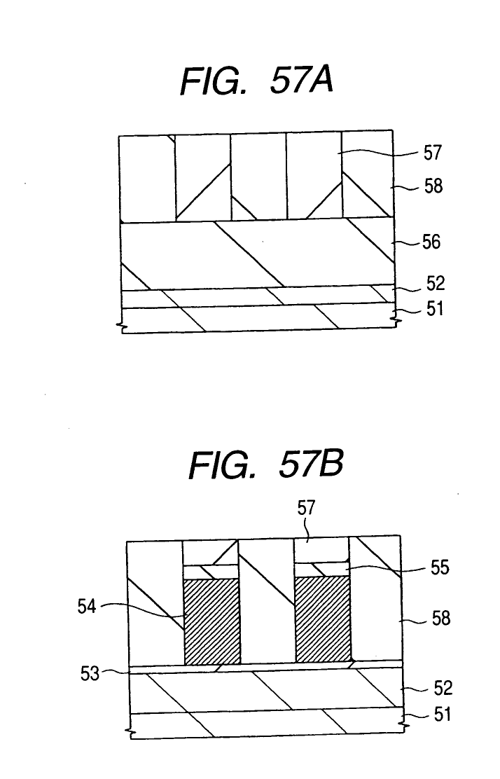

Next, the silicon oxide film 58 is deposited to completely fill the space parts of the pattern consisting of the silicon nitride film 57, the silicon nitride film pattern 55, and the floating gate 54. The line cross-section A-A′ and the line cross-section B-B′ of aforementioned FIG. 53 become FIGS. 56A and 56B, respectively, and the line cross-section C-C′ and the line cross-section D-D′ of FIG. 53 become FIGS. 57A and 57B, respectively, according to the process in which a part of the silicon oxide film 58 is removed by an etch back technique or by CMP to expose the top of the silicon nitride film 57.

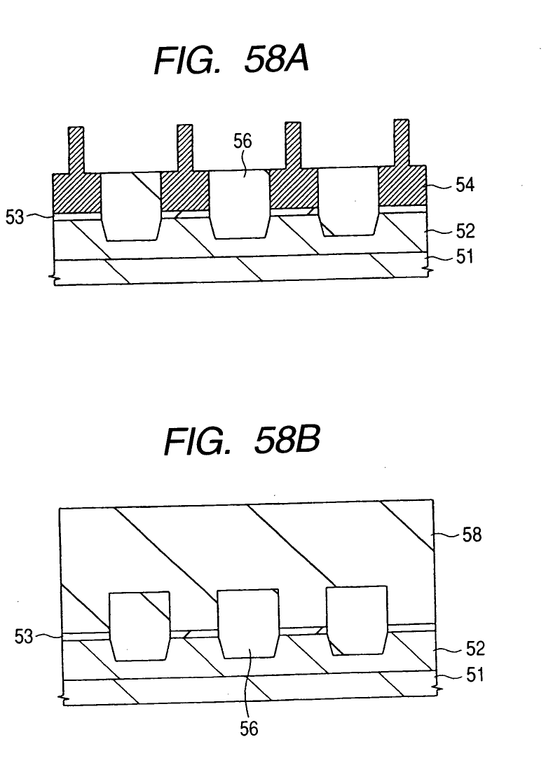

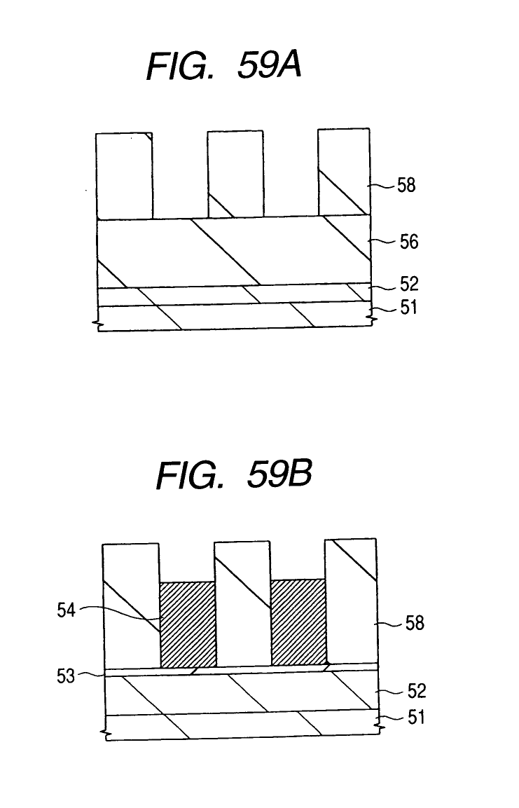

Next, the silicon nitride film 57 and the silicon nitride film pattern 55 are removed by dry-etching using the silicon oxide film 58 as a mask. The line cross-section A-A′ and the line cross-section B-B′ of aforementioned FIG. 53 become FIGS. 58A and 58B, respectively, and the line cross-section C-C′ and the line cross-section D-D′ of FIG. 53 become FIGS. 59A and 59B, respectively.

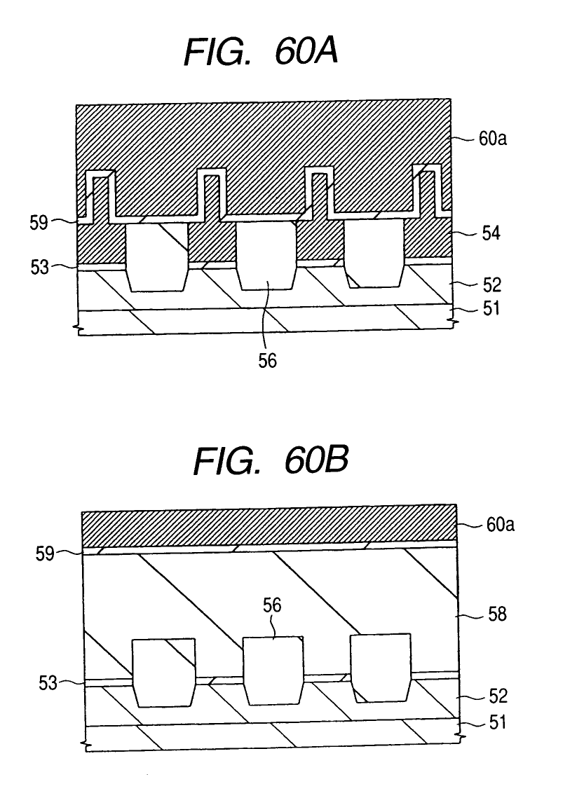

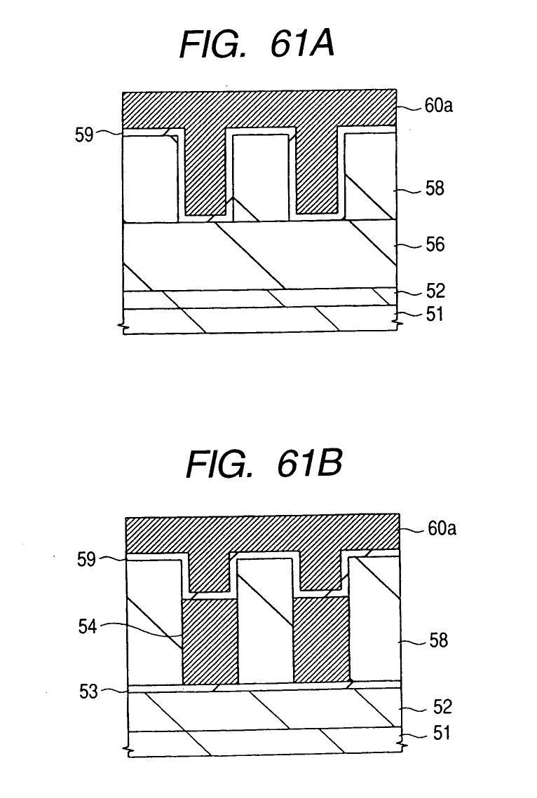

Then, the second insulator film 59, which insulates the gap between the floating gate 54 and the control gate, and the control gate material 60a are deposited in order. The line cross-section A-A′ and the line cross-section B-B′ of aforementioned FIG. 53 become FIGS. 60A and 60B, respectively, and the line cross-section C-C′ and the line cross-section D-D′ of FIG. 53 become FIGS. 61A and 61B, respectively.

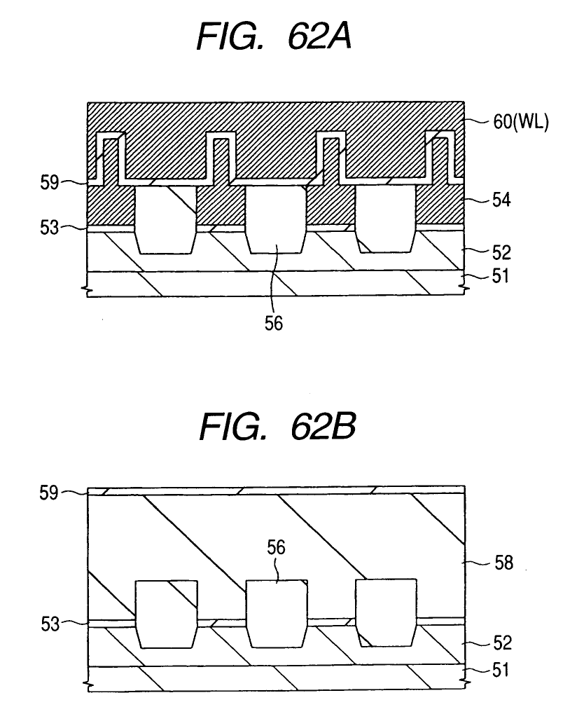

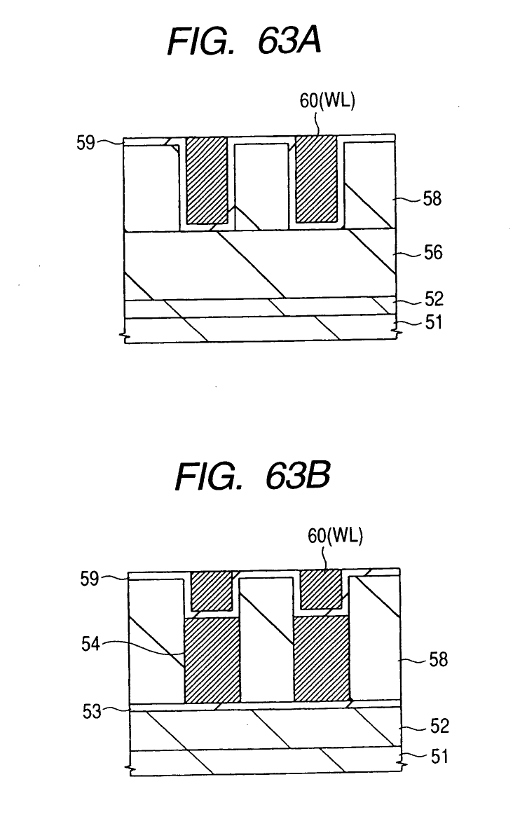

In the next step, the control gate material 60a is removed by CMP or by an etch back technique until the top of the second insulator film 59 or the top of the silicon oxide film 58 are exposed. The line cross-section A-A′ and the line cross-section B-B′ of aforementioned FIG. 53 become FIGS. 62A and 62B, respectively, and the line cross-section C-C′ and the line cross-section D-D′ of FIG. 53 become FIGS. 63A and 63B, respectively.

In this stage, the control gate (first gate) 60 (word line WL) lying along the X direction is formed. The gap of the adjoining control gates 60 is insulated by the silicon oxide film 58. Furthermore, it is not necessary to process the control gate 60 in one step because the floating gate 54 is separated in each memory cell in the stage of aforementioned FIG. 53.

Subsequently, the contact holes reaching the control gate 60 and the well 52, and the contact holes for feeding power to the source and drain diffusion layers located outside of the memory array are formed after forming the interlayer dielectric film. Then, a metallic film is deposited and patterned to be an interconnection, resulting in a memory cell being completed.

In the memory cell of a nonvolatile semiconductor memory fabricated using the above-mentioned process, the part of the floating gate 54 through the control gate 60 and the second insulator film 59 has a smaller dimension than the bottom part of the floating gate 54. Because of this, the opposing area between the floating gates 54 underneath the adjoining word line WL can be reduced while maintaining an adequate area between the floating gate 54 and the control gate 60. That is, maintaining the coupling ratio between the control gate 60 and the floating gate 54 can be compatible with reducing the capacitive coupling between the floating gates 54 underneath the adjoining word line WL. As a result, maintaining the programming/erasing properties can be compatible with reducing the threshold voltage shift caused by changing the adjoining cell conditions.

A nonvolatile semiconductor memory device of the present invention is suitable for a memory device used in personal digital assistants such as a mobile personal computer and digital still camera.

1. A nonvolatile semiconductor memory device comprising:
a first conductive well formed on a silicon substrate;
a plurality of first gates lined up at a uniform spacing through a first insulator film on said silicon substrate along a second direction being parallel to said silicon substrate and perpendicular to a first direction; and
a second gate lying along said first direction formed through a second insulator film covering said first gate,
wherein the dimension along said first direction at a part of said first gate connected to said second insulator film is smaller than the dimension along said first direction at a part of said first gate connected to said first insulator film.

2. A nonvolatile semiconductor memory device as in claim 1, comprising:
a plurality of third gates lying along said second direction connected to said silicon substrate through a third insulator film, to said first gate through a fourth insulator film, and to said second gate through a fifth insulator film and said second insulator film.

3. A nonvolatile semiconductor memory device as in claim 2, comprising:
a plurality of stripe-shaped sixth insulator films lying along said first direction, wherein said first gate is embedded in the space part of said sixth insulator film and the upper surface of said first gate and the space part of said sixth insulator film are embedded in said second gate through said second insulator film.

4. A nonvolatile semiconductor memory device as in claim 2, wherein an inversion layer formed by biasing a voltage to said third gate is used for a data line.

5. A nonvolatile semiconductor memory device as in claim 2, wherein said first gate is formed by one polysilicon layer.

6. A nonvolatile semiconductor memory device as in claim 2, wherein said first gate is formed by two polysilicon layers.

7. A nonvolatile semiconductor memory device as in claim 1, comprising:
a plurality of grooves formed at the surface of said silicon substrate lying along said second direction and third insulator film embedded in said plurality of grooves.

8. A nonvolatile semiconductor memory device as in claim 7, comprising:
a plurality of stripe-shaped fourth insulator films lying along said first direction, wherein said first gate is embedded in the space part of said fourth insulator film, and the upper surface of said first gate and the space part of said fourth insulator film are embedded in said second gate through said second insulator film.

9. A nonvolatile semiconductor memory device as in claim 7, wherein said first gate is formed by one polysilicon layer.

10. A nonvolatile semiconductor memory device as in claim 7, wherein said first gate is formed by two polysilicon layers.

11-25. (canceled)
